(19) United States
(12) Patent Application Publication
(10) Pub. No.: US 2008/0182381 A1
(43) Pub. Date: Jul. 31, 2008

(54) MANUFACTURING METHOD OF SEMICONDUCTOR DEVICE USING STI TECHNIQUE

(76) Inventor: Masahiro KIYOTOSHI, Sagamihara-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/874,292

(22) Filed: Oct. 18, 2007

(30) Foreign Application Priority Data
Oct. 20, 2006 (JP) 2006-286917

(51) Int. Cl. H01L 21/76

(52) U.S. Cl. 438/427; 257/E21.546

(57) ABSTRACT

A first trench and a second trench having width wider than the first trench are simultaneously formed in a main surface area of a semiconductor substrate. The width of an opening portion of the first trench is made narrower by forming a first insulating film on the main surface of the semiconductor substrate and in the first and second trenches. A second insulating film is formed on the first insulating film by use of a high-density plasma-CVD method to form a void in the first trench while covering the opening portion of the first trench, and the second trench is filled with the second insulating film. Then, part of the second insulating film which covers the opening portion is removed by anisotropic etching and the void is filled with an insulating film having fluidity at the film formation time.

### CROSS-REFERENCE TO RELATED APPLICATIONS

This application is based upon and claims the benefit of priority from prior Japanese Patent Application No. 2006286917, filed Oct. 20, 2006, the entire contents of which are incorporated herein by reference.

### BACKGROUND OF THE INVENTION

1. Field of the Invention

This invention relates to a manufacturing method of a semiconductor device using the shallow trench isolation (STI) technique for formation of an element isolation region.

2. Description of the Related Art

The technique for fine patterning of LSIs is rapidly developed to enhance the performance of devices due to high integration density (enhance the operation speed and lower the power consumption) and suppress the manufacturing cost. In recent years, memory elements in which the minimum processing dimension is 90 nm are produced in the case of mass production. Further, in the case of a logic device at the development stage, devices whose gale length is reduced to approximately 30 nm are already experimentally manufactured. Thus, it is predicted that downsizing of the devices is further developed in the future although the technical difficulty is increased.

For the rapid downsizing of the elements, it is important to miniaturize an element isolation region which occupies a large part of the device area. Recently, as a method for forming the isolation region, the STI (Shallow Trench Isolation) technique, which is made suitable for downsizing by filling trenches formed by anisotropic etching with insulating films to form the element isolation region, is used.

The width of the trench formed by the STI technique reaches the trench width of 0.1 μm or less, for example, approximately 90 to 65 nm, but the degree of difficulty in forming the isolation region is rapidly increased in accordance with downsizing. This is because it is necessary to hold the effective distance between the adjacent elements as in the conventional case in order to prevent the insulation property from being reduced due to downsizing of the device although the isolation distance between the elements is determined by the effective distance between the adjacent elements, that is, the shortest distance which circumvents the isolation region.

That is, since the width of the STI trench is reduced due to miniaturization although it is desired to keep the depth of the STI trench at least substantially constant, the aspect ratio of the trench which is filled with the insulating film becomes higher for every downsized generation and the trench filling technique rapidly becomes more difficult.

Particularly, when the half pitch is reduced from 45 to 32 nm in the future, it will become extremely difficult to fill with a silicon oxide film formed by a conventional high-density plasma (HDP)-CVD method, since almost no HDP-CVD deposition occurs in the STI trench when the width of the STI trench becomes less than 30 nm although HDP-CVD method is originally a highly anisotropic film formation method. That is because HDP-CVD film is rapidly close the upper portion of the STI trench when it happens to be formed into an overhang form at the top portion of the STI.

Therefore, use of an insulating film having fluidity at the gap-filling or during the post-annealing such as a spin-on glass (SOG) film, tetraethoxysilane (TEOS)/O₃ film, chemical vapor condensation film or the like as an STI filling material has been extensively studied in recent years (for example, refer to Jpn. Pat. Appln. KOAKI Publication No. 2005-166700).

However, the film density of the flowable insulating film is generally low, a lot of impurities such as C, N, H are contained in the film and the processing resistance thereof is low. Particularly, there is a problem that the wet etching rate is high. In order to solve the above problem, a method for improving the film quality by the heat treatment in the steam atmosphere is generally used, but in the generation of the half pitch of 45 to 32 nm, there occurs a problem that the element region itself is oxidized by oxidation in the steam atmosphere and the width thereof is reduced and it is difficult to sufficiently improve the film quality.

Further, since the flowable film shrinkage is generally large, high tensile stress tends to occur and there occurs a problem that deformation and crystalline defects occur due to stress of the STI region in the narrow active area. Further, since the stress has correlation with the volume of the formed insulating film, there occurs a problem that cracking of the film will occur due to the strong stress in the large STI region.

### BRIEF SUMMARY OF THE INVENTION

According to a first aspect of the present invention, there is provided a manufacturing method of a semiconductor device comprising simultaneously forming a first isolation trench and a second isolation trench having width larger than the first isolation trench in a main surface area of a semiconductor substrate, narrowing width of an opening portion of the first isolation trench by forming a first insulating film on the main surface of the semiconductor substrate and in the first and second isolation trenches, forming void in the first isolation trench while covering the opening portion of the first isolation trench by forming a second insulating film on the first insulating film by use of a high-density plasma-CVD method and filling the second isolation trench with the second insulating film, removing part of the second insulating film which covers the opening portion by anisotropic etching, and filling the void with an insulating film having fluidity at the film formation period.

According to a second aspect of the present invention, there is provided a manufacturing method of a semiconductor device comprising forming a first isolation trench in a main surface area of a semiconductor substrate, forming a first insulating film on the main surface of the semiconductor substrate and in the first isolation trench, filling the first isolation trench with an insulating film having fluidity at the film formation time via the first insulating film by forming an insulating film having fluidity at the film formation time on the first insulating film, forming a second isolation trench of wider width than the first isolation trench, and filling the second isolation trench with a second insulating film by means of a high-density plasma-CVD method.

### BRIEF DESCRIPTION OF THE SEVERAL VIEWS OF THE DRAWING

FIG. 1 is a cross-sectional view showing one manufacturing step of a manufacturing method of a semiconductor device according to a first embodiment of this invention;

FIG. 2 is a cross-sectional view showing one manufacturing step of the manufacturing method of the semiconductor device following the step of FIG. 1;

FIG. 3 is a cross-sectional view showing one manufacturing step of the manufacturing method of the semiconductor device following the step of FIG. 2;

FIG. 4 is a cross-sectional view showing one manufacturing step of the manufacturing method of the semiconductor device following the step of FIG. 3;

FIG. 5 is a cross-sectional view showing one manufacturing step of the manufacturing method of the semiconductor device following the step of FIG. 4;

FIG. 6 is a cross-sectional view showing one manufacturing step of the manufacturing method of the semiconductor device following the step of FIG. 5;

FIG. 7 is a cross-sectional view showing one manufacturing step of the manufacturing method of the semiconductor device following the step of FIG. 6;

FIG. 8 is a cross-sectional view showing one manufacturing step of the manufacturing method of the semiconductor device following the step of FIG. 7;

FIG. 9 is a cross-sectional view showing one manufacturing step of the manufacturing method of the semiconductor device following the step of FIG. 8;

FIG. 10 is a cross-sectional view showing one manufacturing step of the manufacturing method of the semiconductor device following the step of FIG. 9;

FIG. 11 is a cross-sectional view showing one manufacturing step of the manufacturing method of the semiconductor device following the step of FIG. 10;

FIG. 12 is a cross-sectional view showing one manufacturing step of the manufacturing method of the semiconductor device following the step of FIG. 11;

FIG. 13 is a cross-sectional view showing one manufacturing step of the manufacturing method of the semiconductor device following the step of FIG. 12;

FIG. 14 is a cross-sectional view showing one manufacturing step of the manufacturing method of the semiconductor device following the step of FIG. 13;

FIG. 15 is a cross-sectional view showing one manufacturing step of a manufacturing method of a semiconductor device according to a second embodiment of this invention;

FIG. 16 is a cross-sectional view showing one manufacturing step of the manufacturing method of the semiconductor device following the step of FIG. 15;

FIG. 17 is a cross-sectional view showing one manufacturing step of the manufacturing method of the semiconductor device following the step of FIG. 16;

FIG. 18 is a cross-sectional view showing one manufacturing step of the manufacturing method of the semiconductor device following the step of FIG. 17;

FIG. 19 is a cross-sectional view showing one manufacturing step of the manufacturing method of the semiconductor device following the step of FIG. 18;

FIG. 20 is a cross-sectional view showing one manufacturing step of the manufacturing method of the semiconductor device following the step of FIG. 19;

FIG. 21 is a cross-sectional view showing one manufacturing step of the manufacturing method of the semiconductor device following the step of FIG. 20;

FIG. 22 is a cross-sectional view showing one manufacturing step of the manufacturing method of the semiconductor device following the step of FIG. 21;

FIG. 23 is a cross-sectional view showing one manufacturing step of the manufacturing method of the semiconductor device following the step of FIG. 22;

FIG. 24 is a cross-sectional view showing one manufacturing step of the manufacturing method of the semiconductor device following the step of FIG. 23;

FIG. 25 is a cross-sectional view showing one manufacturing step of the manufacturing method of the semiconductor device following the step of FIG. 24;

FIG. 26 is a cross-sectional view showing one manufacturing step of the manufacturing method of the semiconductor device following the step of FIG. 25;

FIG. 27 is a cross-sectional view showing one manufacturing step of the manufacturing method of the semiconductor device following the step of FIG. 26;

FIG. 28 is a view showing an enlarged portion of an STI region of small width shown in FIG. 27;

FIG. 29 is a cross-sectional view showing one manufacturing step of the manufacturing method of the semiconductor device following the step of FIG. 27;

FIG. 30 is a cross-sectional view showing one manufacturing step of the manufacturing method of the semiconductor device following the step of FIG. 29;

FIG. 31 is a cross-sectional view showing one manufacturing step of a manufacturing method of a semiconductor device according to a third embodiment of this invention;

FIG. 32 is a cross-sectional view showing one manufacturing step of the manufacturing method of the semiconductor device following the step of FIG. 31;

FIG. 33 is a cross-sectional view showing one manufacturing step of the manufacturing method of the semiconductor device following the step of FIG. 32;

FIG. 34 is a cross-sectional view showing one manufacturing step of the manufacturing method of the semiconductor device following the step of FIG. 33;

FIG. 35 is a cross-sectional view showing one manufacturing step of the manufacturing method of the semiconductor device following the step of FIG. 34;

FIG. 36 is a cross-sectional view showing one manufacturing step of the manufacturing method of the semiconductor device following the step of FIG. 35;

FIG. 37 is a cross-sectional view showing one manufacturing step of the manufacturing method of the semiconductor device following the step of FIG. 36;

FIG. 38 is a cross-sectional view showing one manufacturing step of the manufacturing method of the semiconductor device following the step of FIG. 37;

FIG. 39 is a cross-sectional view showing one manufacturing step of the manufacturing method of the semiconductor device following the step of FIG. 38;

FIG. 40 is a cross-sectional view showing one manufacturing step of the manufacturing method of the semiconductor device following the step of FIG. 39;

FIG. 41 is a cross-sectional view showing one manufacturing step of the manufacturing method of the semiconductor device following the step of FIG. 40;

FIG. 42 is a cross-sectional view showing one manufacturing step of the manufacturing method of the semiconductor device following the step of FIG. 41;

FIG. 43 is a cross-sectional view showing one manufacturing step of the manufacturing method of the semiconductor device following the step of FIG. 42;

FIG. 44 is a cross-sectional view showing one manufacturing step of the manufacturing method of the semiconductor device following the step of FIG. 43;

FIG. 45 is a cross-sectional view showing one manufacturing step of the manufacturing method of the semiconductor device following the step of FIG. 44;

FIG. 46 is a cross-sectional view showing one manufacturing step of the manufacturing method of the semiconductor device following the step of FIG. 45;

FIG. 47 is a cross-sectional view showing one manufacturing step of the manufacturing method of the semiconductor device following the step of FIG. 46;

FIG. 48 is a cross-sectional view showing one manufacturing step of the manufacturing method of the semiconductor device following the step of FIG. 47;

FIG. 49 is a cross-sectional view showing one manufacturing step of the manufacturing method of the semiconductor device following the step of FIG. 48;

FIG. 50 is a cross-sectional view showing one manufacturing step of the manufacturing method of the semiconductor device following the step of FIG. 49;

FIG. 51 is a cross-sectional view showing one manufacturing step of a manufacturing method of a semiconductor device according to a fourth embodiment of this invention;

FIG. 52 is a cross-sectional view showing one manufacturing step of the manufacturing method of the semiconductor device following the step of FIG. 51;

FIG. 53 is a cross-sectional view showing one manufacturing step of the manufacturing method of the semiconductor device following the step of FIG. 52;

FIG. 54 is a cross-sectional view showing one manufacturing step of the manufacturing method of the semiconductor device following the step of FIG. 53;

FIG. 55 is a cross-sectional view showing one manufacturing step of the manufacturing method of the semiconductor device following the step of FIG. 54;

FIG. 56 is a cross-sectional view showing one manufacturing step of the manufacturing method of the semiconductor device following the step of FIG. 55;

FIG. 57 is a cross-sectional view showing one manufacturing step of the manufacturing method of the semiconductor device following the step of FIG. 56;

FIG. 58 is a cross-sectional view showing one manufacturing step of the manufacturing method of the semiconductor device following the step of FIG. 57;

FIG. 59 is a cross-sectional view showing one manufacturing step of the manufacturing method of the semiconductor device following the step of FIG. 58;

FIG. 60 is a cross-sectional view showing one manufacturing step of the manufacturing method of the semiconductor device following the step of FIG. 59;

FIG. 61 is a cross-sectional view showing one manufacturing step of the manufacturing method of the semiconductor device following the step of FIG. 60;

FIG. 62 is a cross-sectional view showing one manufacturing step of the manufacturing method of the semiconductor device following the step of FIG. 61;

FIG. 63 is a cross-sectional view showing one manufacturing step of the manufacturing method of the semiconductor device following the step of FIG. 62;

FIG. 64 is a cross-sectional view showing one manufacturing step of the manufacturing method of the semiconductor device following the step of FIG. 63;

FIG. 65 is a cross-sectional view showing one manufacturing step of the manufacturing method of the semiconductor device following the step of FIG. 64;

FIG. 66 is a cross-sectional view showing one manufacturing step of the manufacturing method of the semiconductor device following the step of FIG. 65;

FIG. 67 is a cross-sectional view showing one manufacturing step of the manufacturing method of the semiconductor device following the step of FIG. 66;

FIG. 68 is a cross-sectional view showing one manufacturing step of the manufacturing method of the semiconductor device following the step of FIG. 67;

FIG. 69 is a cross-sectional view showing one manufacturing step of a manufacturing method of a semiconductor device according to a fifth embodiment of this invention;

FIG. 70 is a cross-sectional view showing one manufacturing step of the manufacturing method of the semiconductor device following the step of FIG. 69;

FIG. 71 is a cross-sectional view showing one manufacturing step of the manufacturing method of the semiconductor device following the step of FIG. 70;

FIG. 72 is a cross-sectional view showing one manufacturing step of the manufacturing method of the semiconductor device following the step of FIG. 71;

FIG. 73 is a cross-sectional view showing one manufacturing step of the manufacturing method of the semiconductor device following the step of FIG. 72;

FIG. 74 is a cross-sectional view showing one manufacturing step of the manufacturing method of the semiconductor device following the step of FIG. 73;

FIG. 75 is a cross-sectional view showing one manufacturing step of the manufacturing method of the semiconductor device following the step of FIG. 74;

FIG. 76 is a cross-sectional view showing one manufacturing step of the manufacturing method of the semiconductor device following the step of FIG. 75;

FIG. 77 is a cross-sectional view showing one manufacturing step of the manufacturing method of the semiconductor device following the step of FIG. 76;

FIG. 78 is a cross-sectional view showing one manufacturing step of the manufacturing method of the semiconductor device following the step of FIG. 77;

FIG. 79 is a cross-sectional view showing one manufacturing step of the manufacturing method of the semiconductor device following the step of FIG. 78;

FIG. 80 is a cross-sectional view showing one manufacturing step of the manufacturing method of the semiconductor device following the step of FIG. 79;

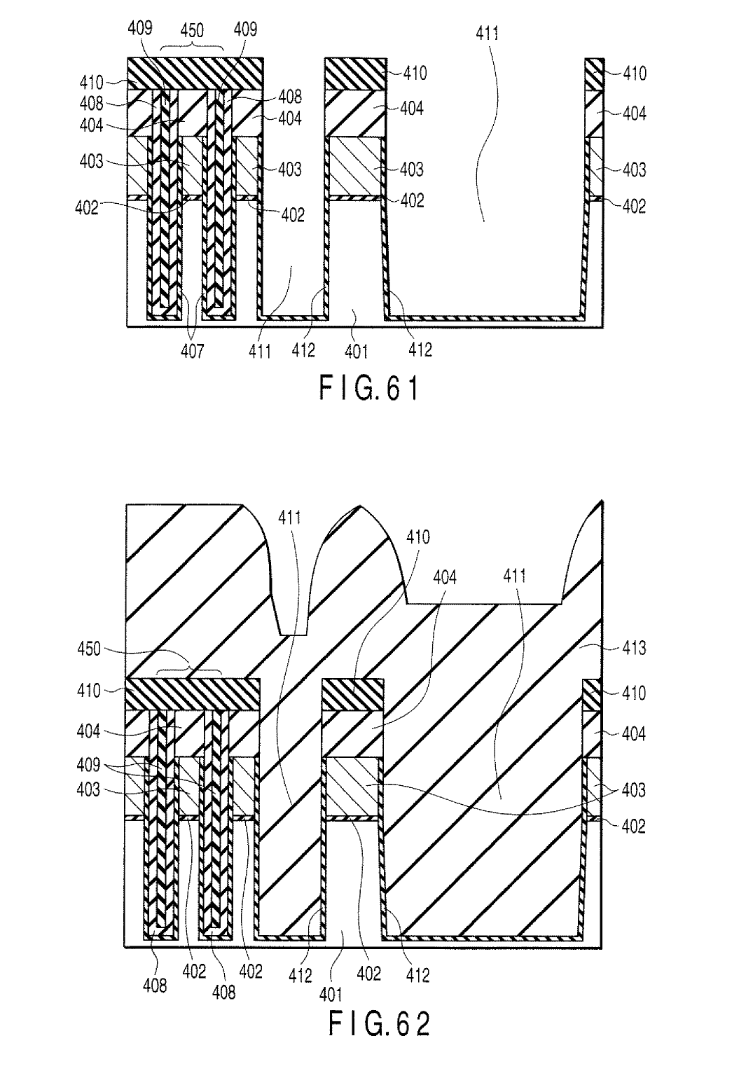

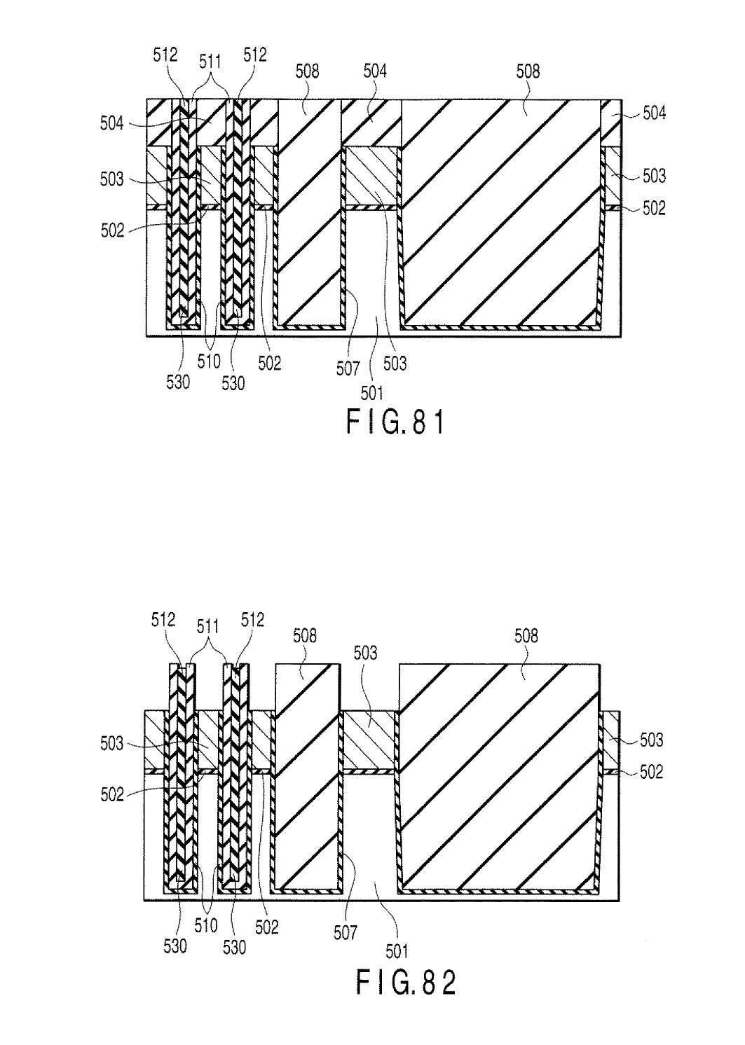

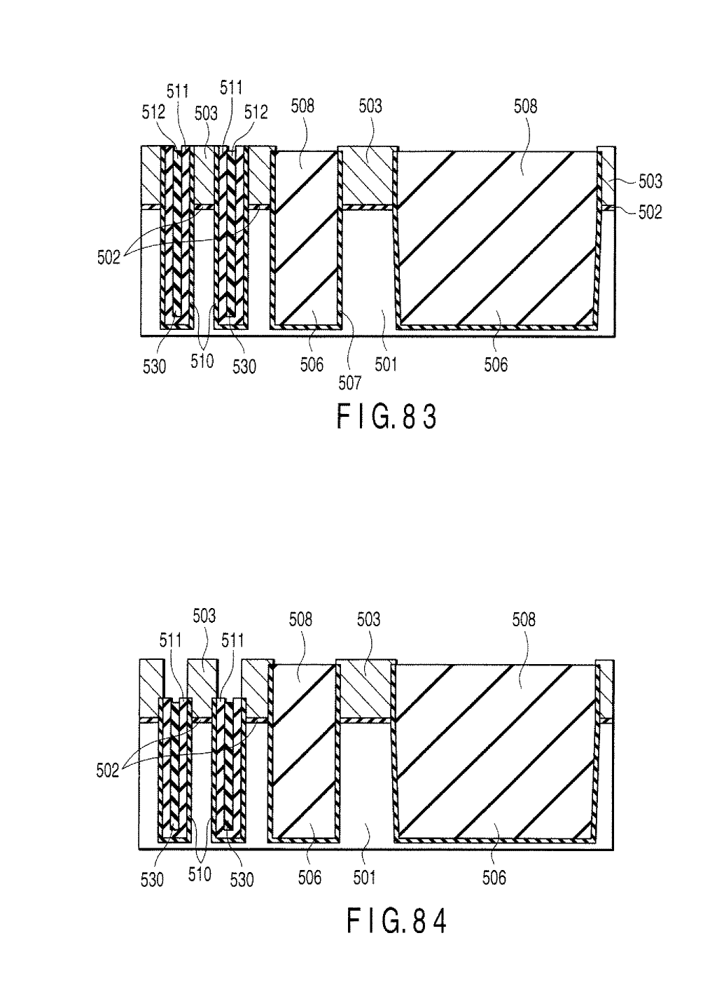

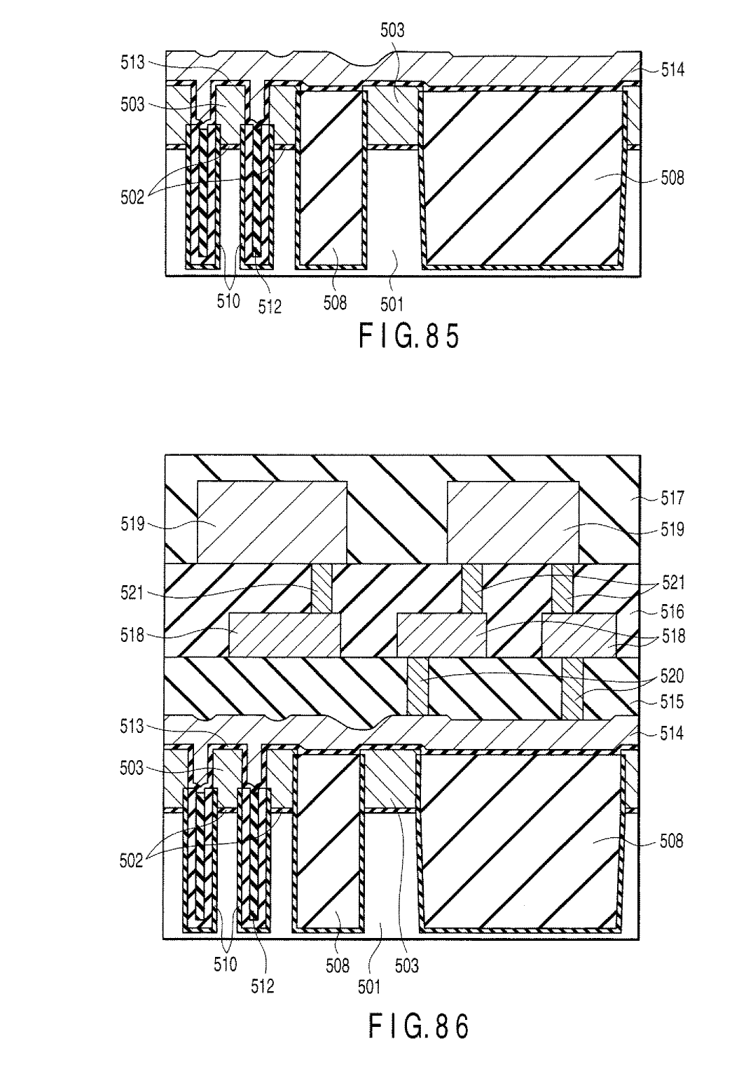

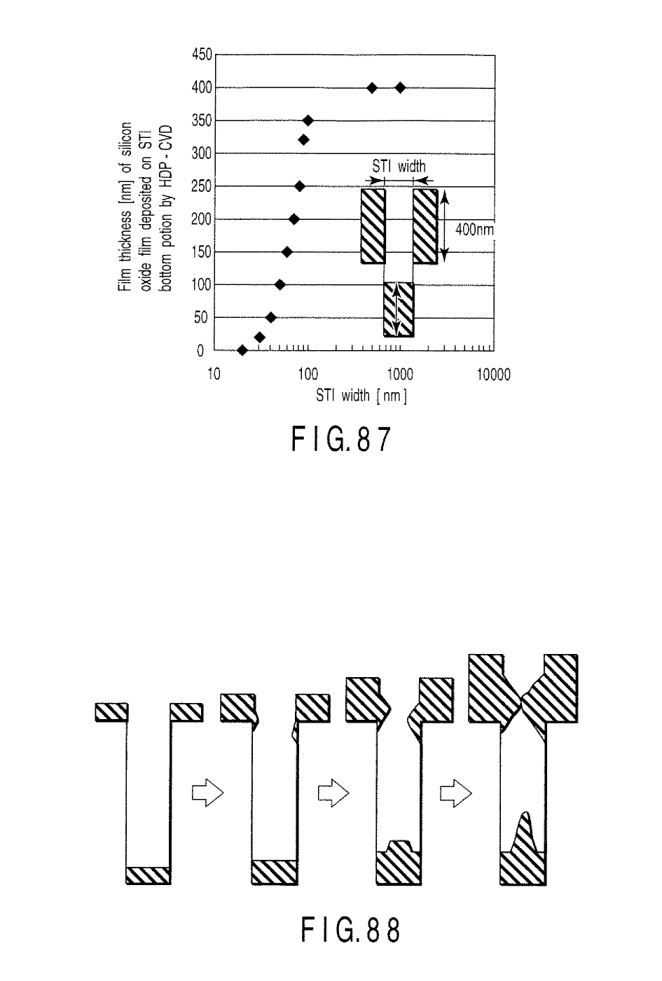

FIG. 61 is a cross-sectional view showing one manufacturing step of the manufacturing method of the semiconductor device following the step of FIG. 80;

FIG. 82 is a cross-sectional view showing one manufacturing step of the manufacturing method of the semiconductor device following the step of FIG. 81;

FIG. 83 is a cross-sectional view showing one manufacturing step of the manufacturing method of the semiconductor device following the step of FIG. 82;

FIG. 84 is a cross-sectional view showing one manufacturing step of the manufacturing method of the semiconductor device following the step of FIG. 83;

FIG. 85 is a cross-sectional view showing one manufacturing step of the manufacturing method of the semiconductor device following the step of FIG. 84;

FIG. 86 is a cross-sectional view showing one manufacturing step of the manufacturing method of the semiconductor device following the step of FIG. 85;

FIG. 87 is a diagram showing the relationship between the width (nm) of an STI region and the film thickness (nm) of a silicon oxide film deposited on the bottom portion of the STI region in a case where the silicon oxide film is formed by use of the HDP-CVD method; and

FIG. 88 is a schematic cross-sectional view showing a process of covering the upper portion of the trench in the STI region in the film formation step of the HDP-CVD method.

### DETAILED DESCRIPTION OF THE INVENTION

### First Embodiment

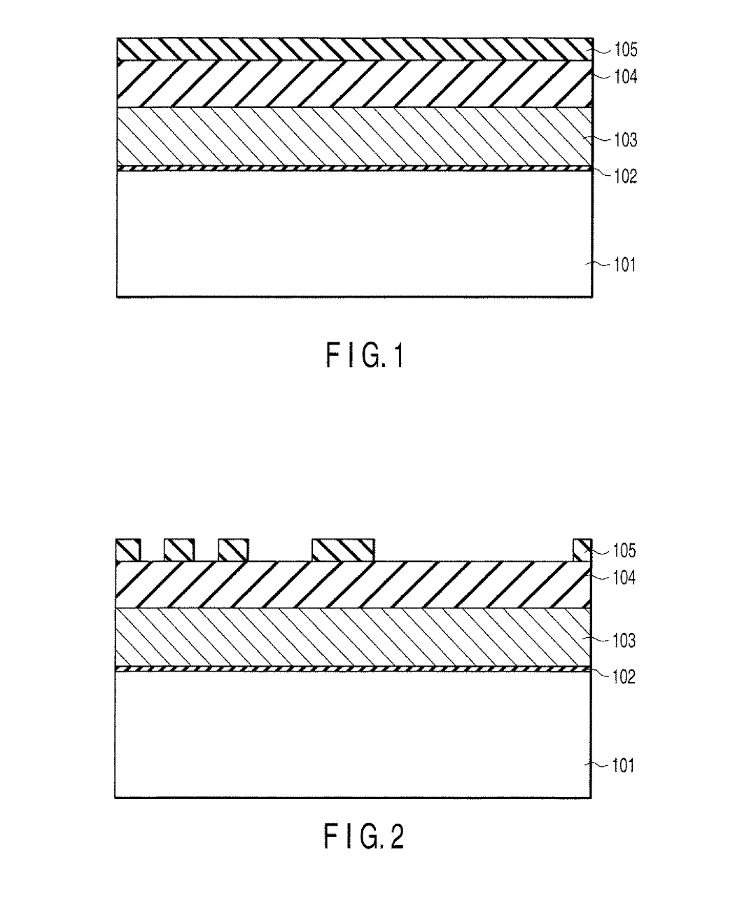

A manufacturing method of a semiconductor device according to a first embodiment of this invention is explained with reference to FIGS. 1 to 14.

The present embodiment is one example of a manufacturing method of a flash memory and indicates a case wherein a gate insulating film and a gate electrode film used as floating gates are previously formed on a semiconductor substrate and then STI regions are formed.

First, as shown in FIG. 1, a silicon thermal oxynitride film 102 used as a gate insulating film is formed to a thickness of approximately 8 nm on a semiconductor substrate 101, a P-doped polysilicon film 103 used as floating gates is formed to a thickness of approximately 120 nm and a silicon nitride film 104 used as a polishing stopper for a chemical mechanical polishing (CMP) process is formed to a thickness of approximately 100 nm. Then, a CVD silicon oxide film 105 used as a mask for reactive ion etching (RIE) is formed on the entire surface of the silicon nitride film 104 (FIG. 1) and a photoresist film is formed by coating (not shown).

Next, the photoresist film is processed by the normal lithography technique and the silicon oxide film 105 is etched by the RIE process with the photoresist film used as a mask to form a hard mask 105 as shown in FIG. 2. The remaining photoresist film is etched and removed by use of a mixture of a hydrogen peroxide sulfuric acid mixture and ashing (FIG. 2).

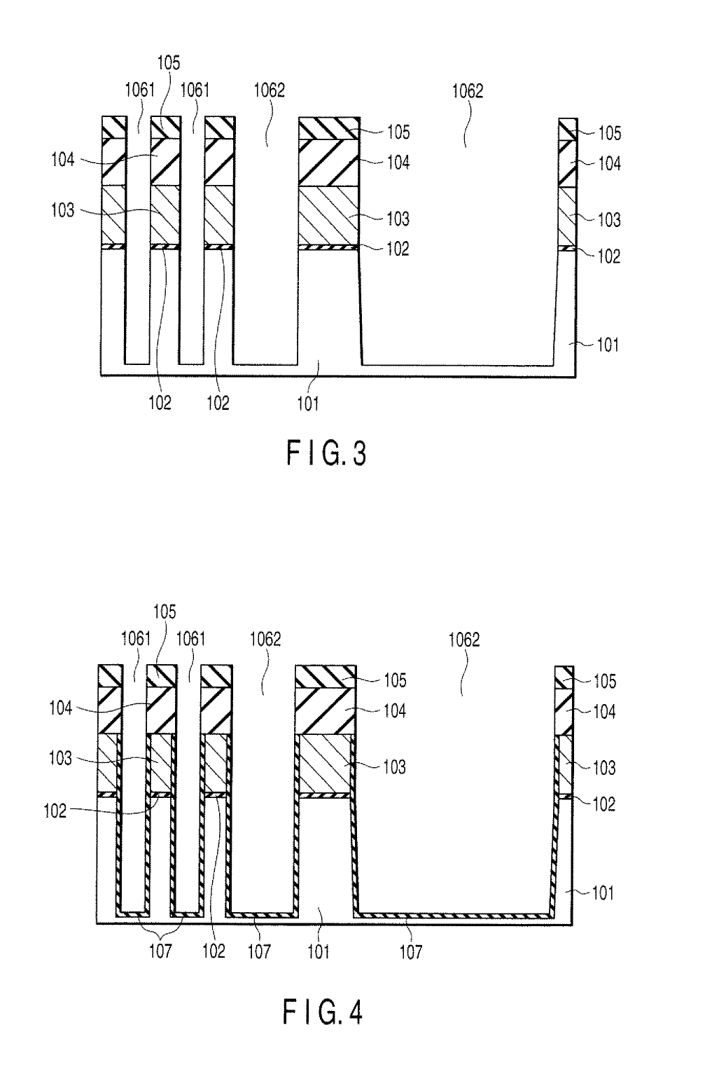

Then, as shown in FIG. 3, the silicon nitride film 104, P-doped polysilicon film 103, silicon thermal oxynitride film 102 and semiconductor substrate 101 are sequentially processed by the RIE process using the hard mask 105 formed of the CVD silicon oxide film.

As a result, isolation trenches 1061, 1062 used as STI regions with the etching depth of 220 nm are formed in the main surface area of the semiconductor substrate 101. In this case, the width of the isolation trench 1061 used as the STI region of the cell portion is set to 45 nm and the width of the isolation trench 1062 used as the STI region of the peripheral circuit is set to 100 nm or more.

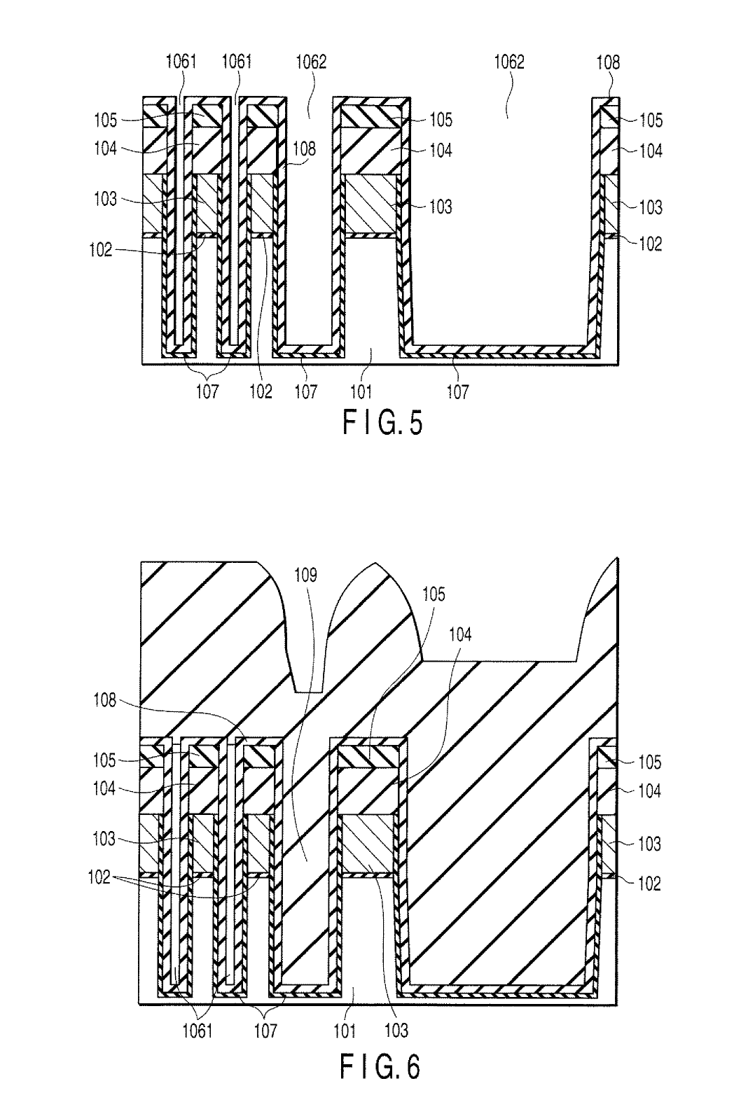

After this, as shown in FIG. 4, the inner surfaces of the isolation trenches 1061, 1062 are thermally oxidized to form silicon thermal oxide films 107 of film thickness approximately 3 nm. Further, as shown in FIG. 5, a silicon oxide film 108 (first insulating film) which is a liner insulating film of film thickness approximately 15 nm is conformally formed on the entire surface of the resultant semiconductor structure by use of the CVD method using silane and N₂O as source gases. As a result, the opening width of the isolation trench 1061 in the cell portion is narrowed by the silicon oxide film 108 and set to approximately 10 nm (FIG. 5).

If an attempt is made to entirely fill the isolation trenches 1061 with the silicon oxide film 108 (unlike the present embodiment), the liner insulating film is formed with the uniform film thickness, and therefore, a seam remains in the central portion of each trench. If the seam is formed in the upper portion of the STI region, there occurs a problem that an etchant penetrates the seam to etch the STI region is during the wet etching.

Next, as shown in FIG. 6, a silicon oxide film 109 (second insulating film) is deposited and formed to a thickness of 500 nm on the entire surface of the resultant semiconductor structure by use of the high-density plasma (HDP)-CVD method. Specifically, the film is formed by use of silane/oxygen/hydrogen, helium or a mixture of the gases in a condition of the film formation temperature of 600 to 800° C., the bias of 2 to 3 kW and the deposition-rate-to-sputter-rate (D/S) ratio of 6 to 11.

In the HDP-CDV process, an anisotropic film formation process is performed by forming the film in the state where the film formation (deposition) and etching (sputter) processes are simultaneously performed. The D/S ratio is the ratio of the film formation rate (deposition rate) to the etching rate (sputter rate) and is a quantity which features the shape of the formed film. The HDP-CVD silicon oxide film 109 formed in FIG. 6 has a preferable film quality since the film is formed with high density by use of plasma energy at relatively high temperatures.

In the present embodiment, since the width of the isolation trench 1061 in the cell portion is reduced to 20 nm or less by formation of the silicon oxide film 108, the HDP-CVD silicon oxide film 109 instantly covers the upper portions of the isolation trenches 1061.

This is because almost no deposition onto the bottom portion of the STI region occurs when the STI width becomes less than 30 nm as shown in FIG. 87 although the HDP-CVD method is a film formation method originally having a high anisotropic property. FIG. 87 is a diagram showing the relation between the STI width (nm) when the silicon oxide film of film thickness 400 nm is formed on the substrate by use of the HDP-CVD method and the film thickness (nm) of the silicon oxide film deposited at this time on the bottom portion of the STI region.

When the STI width becomes smaller, a film happens to be formed on the end portion of the upper portion of the trench of the STI region into an overhung form as shown in FIG. 88 and then the film becomes a core and instantly grows to cover the upper portion of the trench of the STI region.

That is, when the trench width is in the range of approximately 50 to 70 nm, the overhung portion is eliminated by an etching process at the HDP-CVD film formation time. However, when the filling process of the STI region with the trench width set less than 30 nm is performed, the upper portion of the trench is covered before the overhung portion is eliminated. As a result, as shown in FIG. 87, when the decreased STI width (the width of the isolation trench) becomes 20 nm or less, almost no HDP-CVD silicon oxide film is deposited onto the bottom portion of the STI region.

In the case of the present embodiment, the width of the isolation trench 1061 used as the narrow STI portion is set to 45 nm before the silicon oxide film 108 which is a liner insulating film is formed and is a trench of small width so that deposition of a silicon oxide film will be incomplete even if the film is formed in this state by the HDP-CVD process. Therefore, in order to completely fill the isolation trench 1061 in the later process step with an another film, that is, an insulating film having fluidity at the film formation time, the trench width is further reduced by use of the silicon oxide film 108 to temporarily cover the upper portion of the isolation trench 1061 with the HDP-CVD silicon oxide film 109.

As a result, in the peripheral circuit portion or the like whose width is 100 nm or more (FIG. 6), the isolation trench 1061 used as the narrow STI portion is not substantially filled with the HDP-CVD silicon oxide film 109, and the Isolation trench 1062 used as the STI region is completely filled with the HDP-CVD silicon oxide film 109.

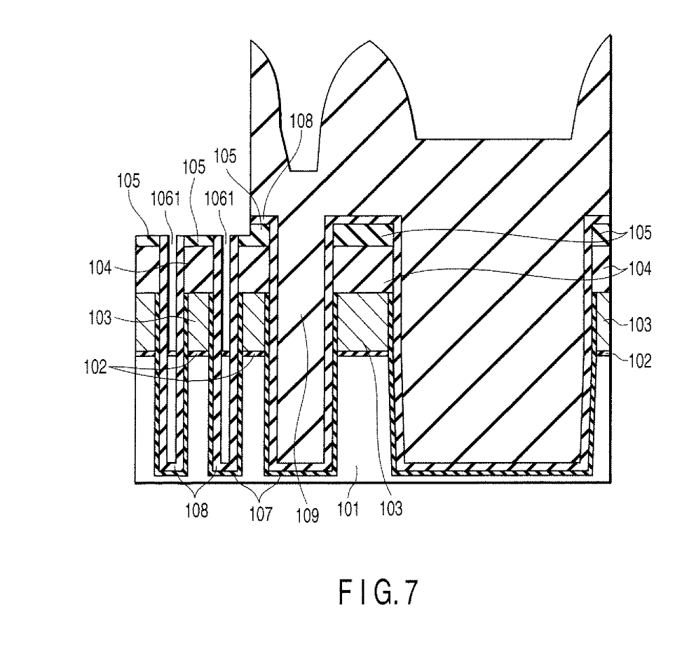

Next, as shown in FIG. 7, the HDP-CVD silicon oxide film 109 on the isolation trenches 1061 is removed by use of the heretofore known lithography technique and reactive ion etching technique to open the upper portions of the isolation trenches 1061.

At this time, the end portion of the silicon nitride film 104 used as a stopper in the later CMP process is protected by the silicon oxide film 105 used as a hard mask for STI trench formation. Thus, it becomes possible to solve a problem that the manufacturing yield of transistors is lowered because the end portion of the silicon nitride film 104 used as the CMP stopper is eroded.

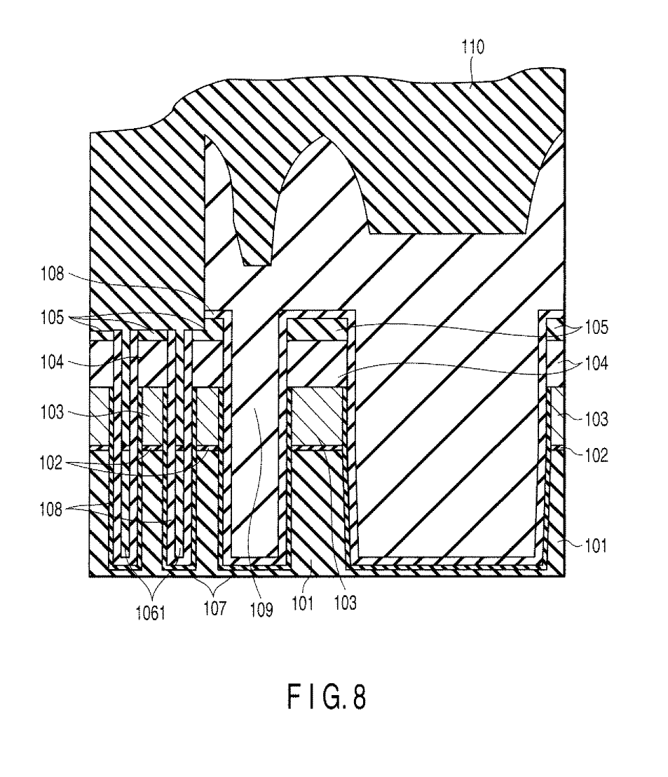

Next, as shown in FIG. 8, a polysilazane film 110 is formed on the entire surface of the resultant semiconductor structure to completely fill the isolation trenches 1061. The polysilazane film 110 is an SOG film having fluidity at the film formation time, as will be described below, and can fill the isolation trenches 1061 without generating voids.

Further, since a large step difference occurs in the HDP-CVD silicon oxide film 109 which is partially recessed by the RIE process in correspondence to the cell portion, it is difficult to make fiat the resultant semiconductor structure as it is in the later CMP process. However, since the polysilazane film 110 is in a liquid state at the coating time, it preferentially flows into the recessed or concave portion and a relatively flat shape can be easily attained. Therefore, an advantage that the flat shape can be easily attained by the later CMP process can be attained. Further, seams remaining when the isolation trenches 1061 are fully filled with the silicon oxide film 108 used as the liner insulating film are not formed.

The polysilazane film 110 is formed as follows although a detailed explanation thereof is not shown in the drawing.

First, a perhydropolysilazane [(SiH₂NH)ₙ] with the mean molecular weight of 2000 to 6000 is dispersed into xylene, dibuthylether and the like to form a perhydropolysilazane solution. The perhydropolysilazane solution is coated on the main surface of the semiconductor substrate 101 by a spin coating method. In this case, the liquid is coated, and therefore, the perhydropolysilazane can fill the isolation trench 1061 of narrow width 20 nm or less as in the present embodiment without causing voids and seams (unfilled portions in the seam form). For example, as the condition of the spin coating method, the rotation speed of the semiconductor substrate 101 is 1200 rpm, the rotation time is 30 seconds, a drop amount of the perhydropolysilazane solution is 2 cc and the target coating film thickness is 450 nm immediately after baking.

Next, the semiconductor substrate 101 having the coated film formed thereon is heated to 150° C. on the hot plate and a solvent in the perhydropolysilazane solution is evaporated by baking the same in the inert gas atmosphere. In this state, carbon or hydrocarbon caused by the solvent remains as impurity in the coated film by approximately several percent to ten-odd percent and a perhydropolysilazane film is set in a state closer to the state of the silicon nitride film with low density containing a remaining solvent.

Then, C, N remaining in the film are removed by subjecting the perhydropolysilazane film to a steam-oxidation process. Further, the density of the polysilazane film 110 is enhanced by performing the annealing process in the inert gas atmosphere of 800 to 1000° C.

Next, as shown in FIG. 9, the polysilazane film 110, HDP-CVD silicon oxide film 109, silicon oxide film 105 and silicon oxide film 108 are polished by the CMP technique with the silicon nitride film 104 used as a stopper. Thus, the polysilazane film 110 remains only in the isolation trenches 1061 and the HDP-CVD silicon oxide film 109 remains only in the isolation trenches 1062.

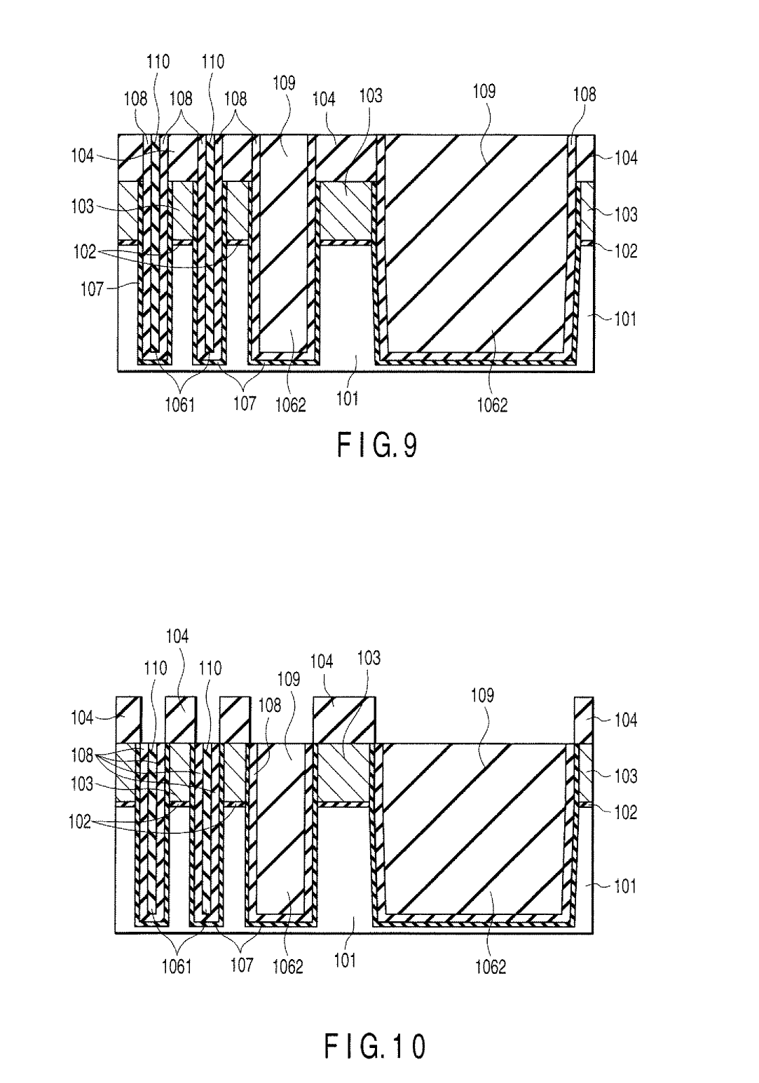

Then, as shown in FIG. 10, the silicon oxide film 108 and the filling insulating films (HDP-CVD silicon oxide film 109 and polysilazane film 110) remaining in the isolation trenches 1061 and 1062 are etched back by approximately 100 nm.

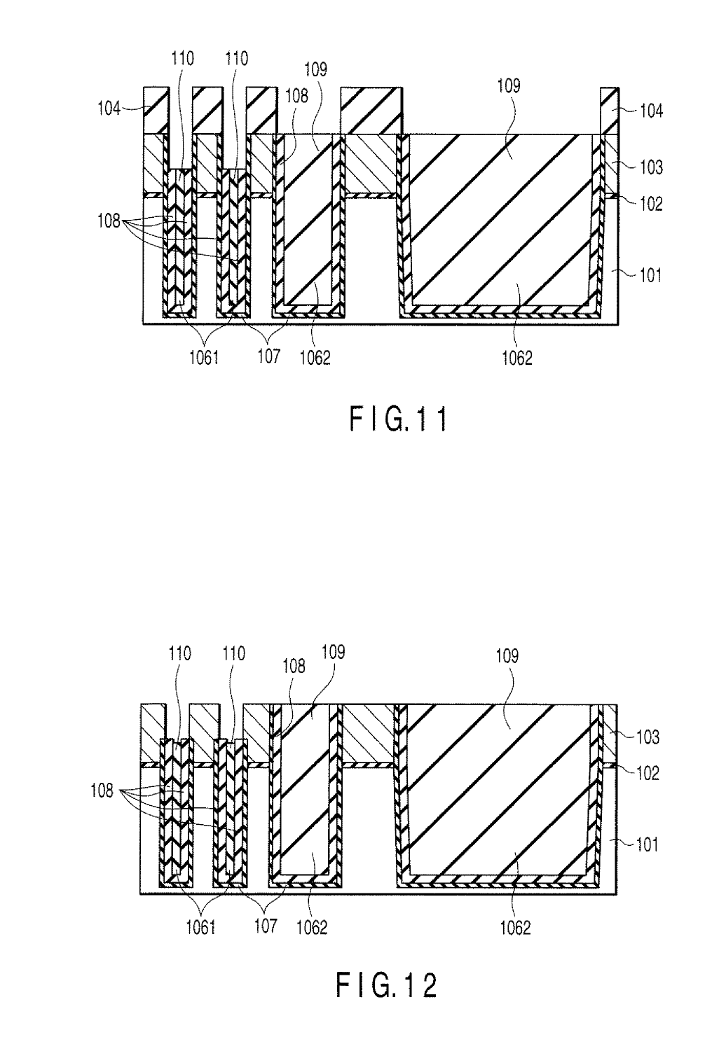

Further, as shown in FIG. 11, the inner portions of the isolation trenches 1061 used as STI regions in the cell portion are further etched back by approximately 40 nm by the heretofore known lithography technique and RIE technique.

Next, as shown in FIG. 12, the silicon nitride film 104 is removed in hot phosphoric acid to form the STI regions in the isolation trenches 1061 and 1062. In this case, the upper portions of the polysilazane films 110 are slightly depressed due to a difference in the etching rate in the hot phosphoric acid.

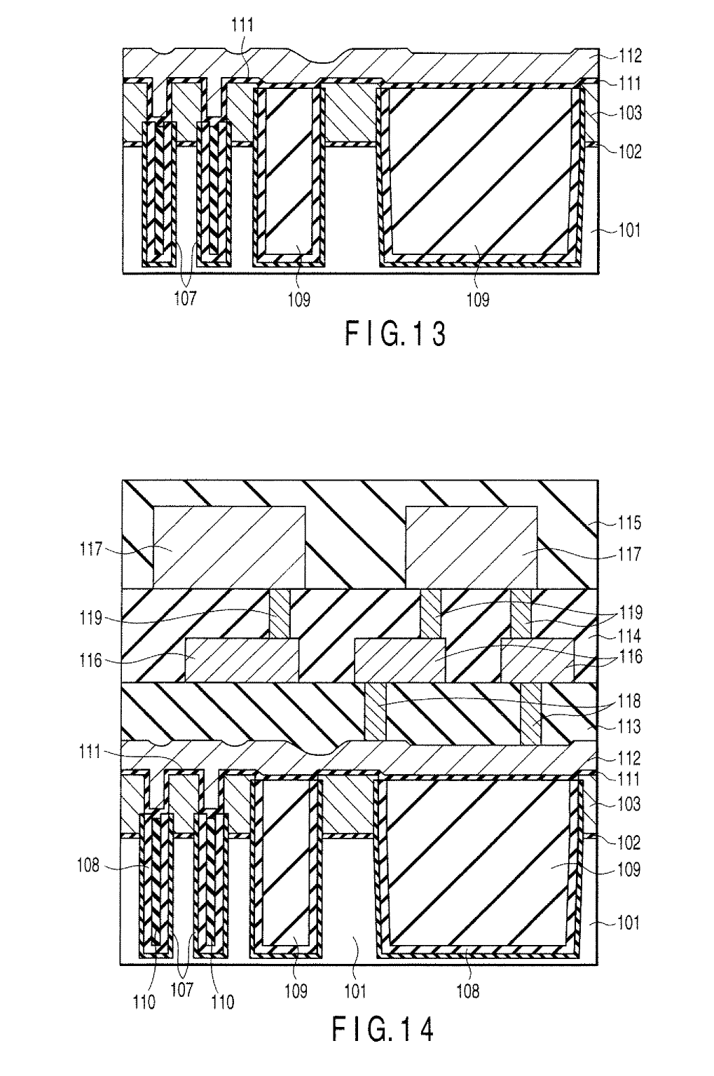

Then, as shown in FIG. 13, an ONO film 111 used as an inter-polysilicon gate dielectric film (IPD) is formed and a P-doped polysilicon film 112 used as control gate electrodes is formed. The P-doped polysilicon film 112, ONO film 111 and P-doped polysilicon film 103 are sequentially processed by the heretofore known lithography technique and RIE technique to form control gates and floating gates (not shown).

After this, a device with the final structure is formed by forming inter-level dielectric films (ILD) 113, 114, 115 and a multi-layered wiring structure having wirings 116, 117 and contact plugs 118, 119 as shown in FIG. 14 although a detailed explanation of the process is omitted.

As described above, the STI region of small width and the STI region of large width can be separately is formed without adding a lithography process by the manufacturing method of the semiconductor device of the present embodiment.

That is, the STI region of small width of approximately 45 nm in the cell portion can be filled without causing voids and seams by use of an insulating film having fluidity at the film formation time and a high filling property. At the same time, the structure in which the STI region of large width in the peripheral circuit portion is filled only with an HDP-CVD silicon oxide film which is excellent in the processing resistance can be realized.

Since the STI region of large width mainly used as the peripheral circuit portion can be filled only with the HDP-CVD silicon oxide film, the STI region will not be influenced by strong stress caused when the STI region is filled with a flowable insulating film as in the case of the STI region of small width in the cell portion. Therefore, it is possible to attain an advantage that film cracking and transistor threshold voltage shift caused by STI impurities can be avoidable.

Further, conventionally, in order to form a hybrid structure using both of a flowable insulating film and an HDP-CVD silicon oxide film, two CMP steps are required. Therefore, there occurs a problem that the number of process steps is increased and the process margin is lowered due to increased complication of the process. However, in the present embodiment, it is sufficient to perform the CMP step only one time and, as a result, the process can be simplified.

In the present embodiment, the polysilazane film is used as the flowable insulating film to fill the trenches of narrow width used as the STI region, but the STI trenches of narrow width can be filled with a different type of Soc film, for example, a hydrogen silsesquioxane (HSQ) film ((HSiO_{3/2})ₙ, where n is an integer) or chemical vapor condensation film.

### Second Embodiment

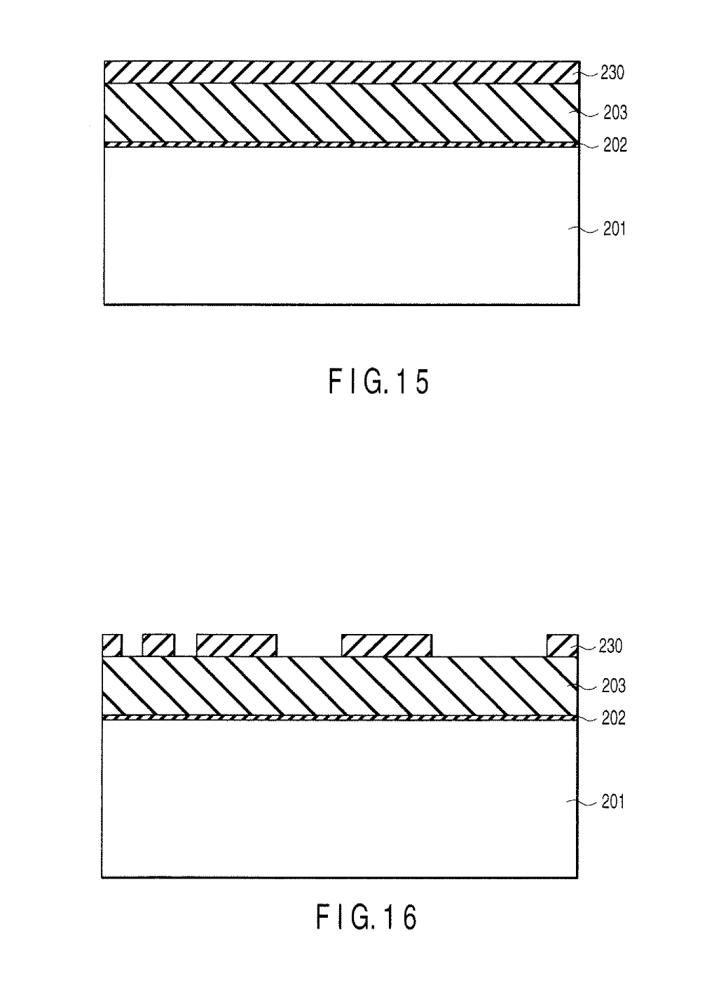

A manufacturing method of a semiconductor device according to a second embodiment of this invention is explained with reference to FIGS. 15 to 30.

The present embodiment is one example of a manufacturing method of a logic device and, in this case, STI regions are first formed on a semiconductor substrate and then transistors are formed. In the present embodiment, the manufacturing method for realizing an STI structure which is resistant to wet etching in the multi-gate oxide process is shown.

First, as shown in FIG. 15, a silicon oxide film 202 used as a buffer film is formed to 2 nm on a semiconductor substrate 201 and a silicon nitride film 203 used as a CMP polishing stopper is formed to 100 nm. Then, a CVD silicon oxide film 230 used as a mask for reactive ion etching (RIE) is formed on the entire surface of the silicon nitride film 203 (FIG. 15) and a photoresist film is further coated (not shown).

Next, the photoresist film is processed by use of the normal lithography technique and the silicon oxide film 230 is etched by the RIE process with the photoresist film used as a mask to form a hard mask 230 as shown in FIG. 16. The photoresist film is etched and removed by using a mixture of a hydrogen peroxide sulfate solution and asher (FIG. 16).

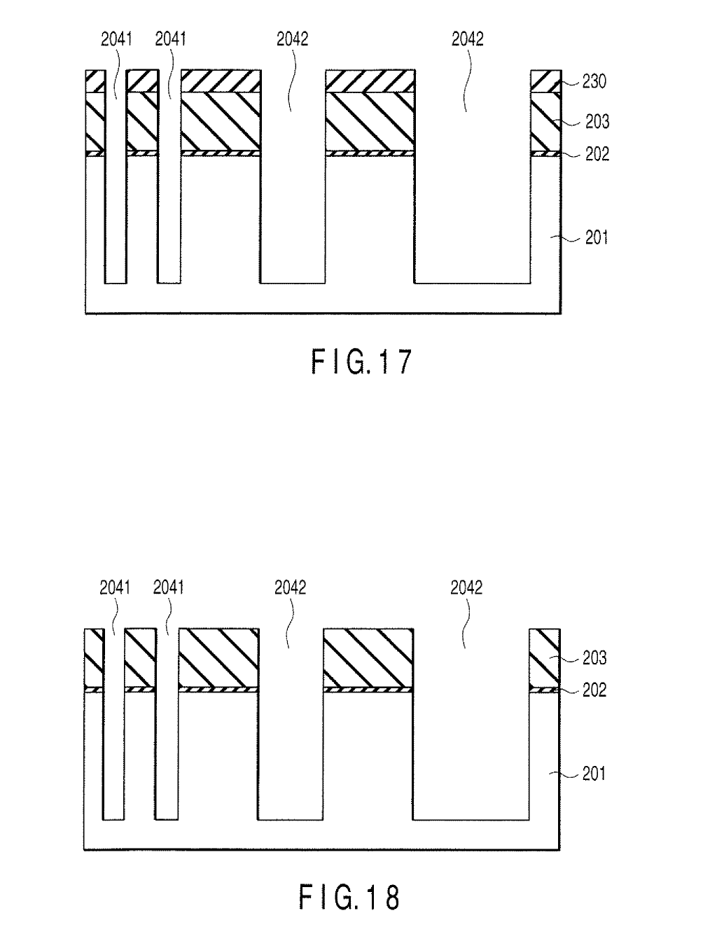

Next, as shown in FIG. 17, the silicon nitride film 203, silicon thermal oxide film 202 and semiconductor substrate 201 are sequentially processed to form trenches 2041, 2042 with the etching depth 250 nm in the semiconductor substrate by the RIE process using the hard mask 230 which is a CVD silicon oxide film. In this case, the width of the trench 2042 is larger than that of the trench 2041. Then, as shown in FIG. 18, the CVD silicon oxide film 230 of the mask member is selectively removed by use of hydrofluoric acid vapor.

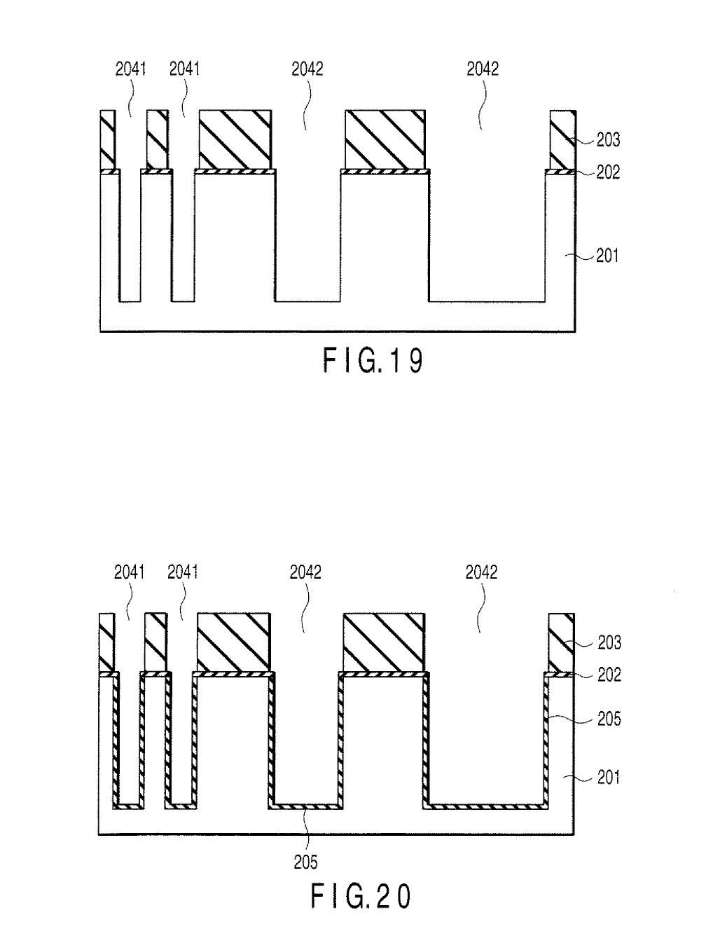

Next, as shown in FIG. 19, the silicon nitride film 203 is etched by approximately 5 nm in hot phosphoric acid. At this time, the width of the trench 2041 used as the STI region of narrowest width is 32 nm. As described above, the isolation trenches 2041, 2042 used as the STI regions are formed.

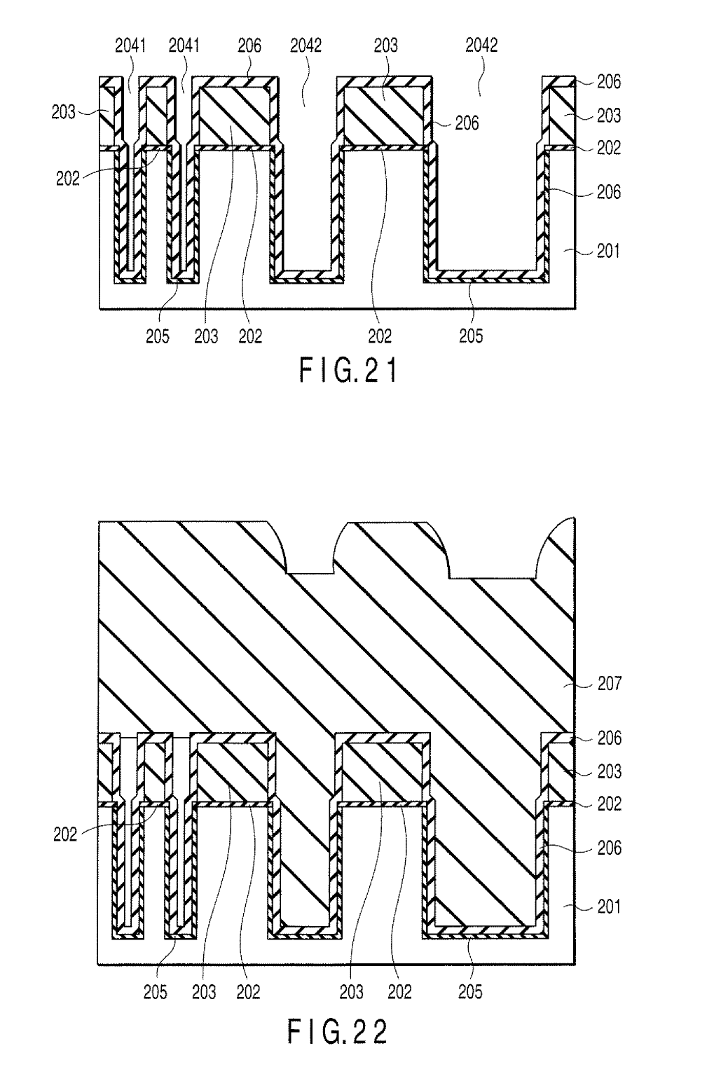

After this, as shown in FIG. 20, the inner surfaces of the isolation trenches 2041, 2042 are thermally oxidized to form silicon thermal oxide films 205 with the thickness of 3 nm. Next, as shown in FIG. 21, a silicon oxide film 206 (first insulating film) which is a liner insulating film is formed to a thickness of 12 nm on the entire surface of the resultant semiconductor structure by use of the LPCVD method using TEOS as a raw material.

Thus, the width of the isolation trench 2041 which is first set to 32 nm is narrowed, a space with the width of 8 nm is provided in the center portion of the trench below the main surface of the substrate 201 and a space with the width of 18 nm is provided in the upper portion of the trench since the silicon nitride film 203 pulled back is performed with hot phosphoric acid (FIG. 21).

Then, as shown in FIG. 22, an HDP-CVD silicon oxide film 207 (second insulating film) is formed to a thickness of 500 nm on the entire surface of the resultant semiconductor structure. The film formation condition is the same as that of the first embodiment. At this time, as in the first embodiment, the isolation trenches 2041 used as the STI regions of small width are not fully filled with the HDP-CVD silicon oxide film 207, and only the upper portions of the isolation trenches 2041 are covered with the HDP-CVD silicon oxide film 207. Therefore, the structure in which voids are left behind in the isolation trenches 2041 is provided (FIG. 22).

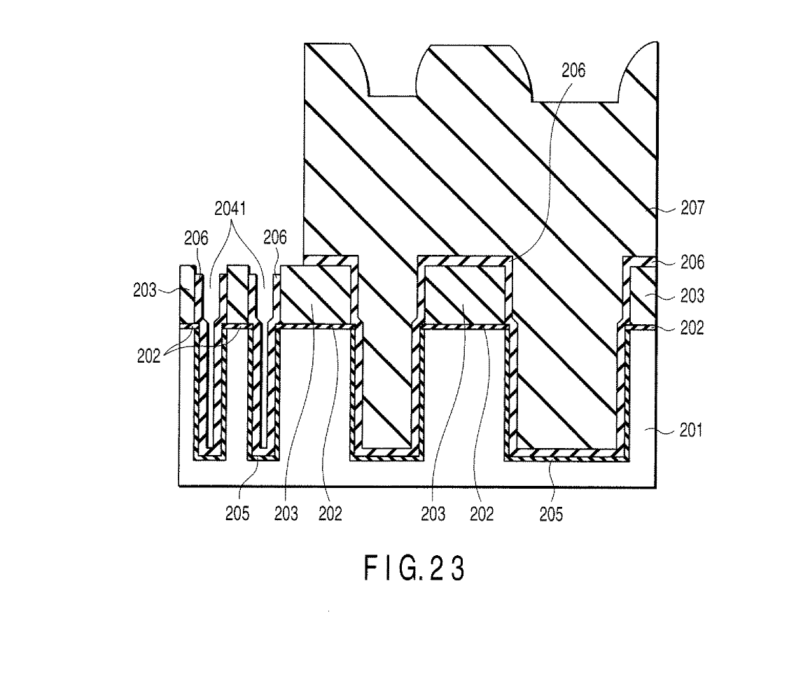

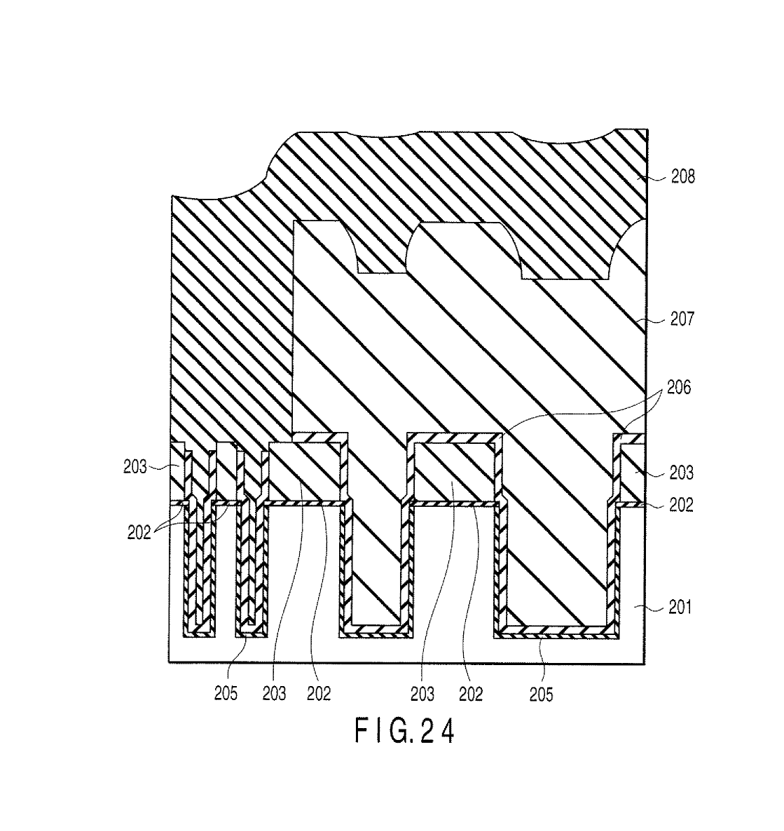

Next, as shown in FIG. 23, part of the HDP-CVD silicon oxide film 207 which covers the isolation trenches 2041 is removed by the known lithography technique and reactive ion etching technique to open the upper potions of the voids formed in the isolation trenches 2041.

Then, as shown in FIG. 24, a chemical vapor condensation film 208 is formed on the entire surface of the resultant semiconductor structure by using silane and hydrogen peroxide as source gases. Since the chemical vapor condensation film 208 has fluidity at the film formation time and has a property of selective growth from the bottom portion of the narrow space, the space with the width of approximately 8 nm near the bottom portion of the isolation trench 2041 can be filled therewith.

In order to form the chemical vapor condensation film 208, the semiconductor substrate 201 is cooled to 0° C. in a vacuum chamber and silane and hydrogen peroxide are introduced to react therewith. Thus, the chemical vapor condensation film 208 having high fluidity at the film formation time is formed. A narrow isolation trench of width 10 nm or less can be filled with the chemical vapor condensation film.

Further, the chemical vapor condensation film 208 is oxidized in the low-pressure steam atmosphere at 300° C. and 600 torr. In addition, a chemical vapor condensation film 208 having a good insulating property can be realized by performing a nitrogen annealing process at 800° C. for 30 minutes.

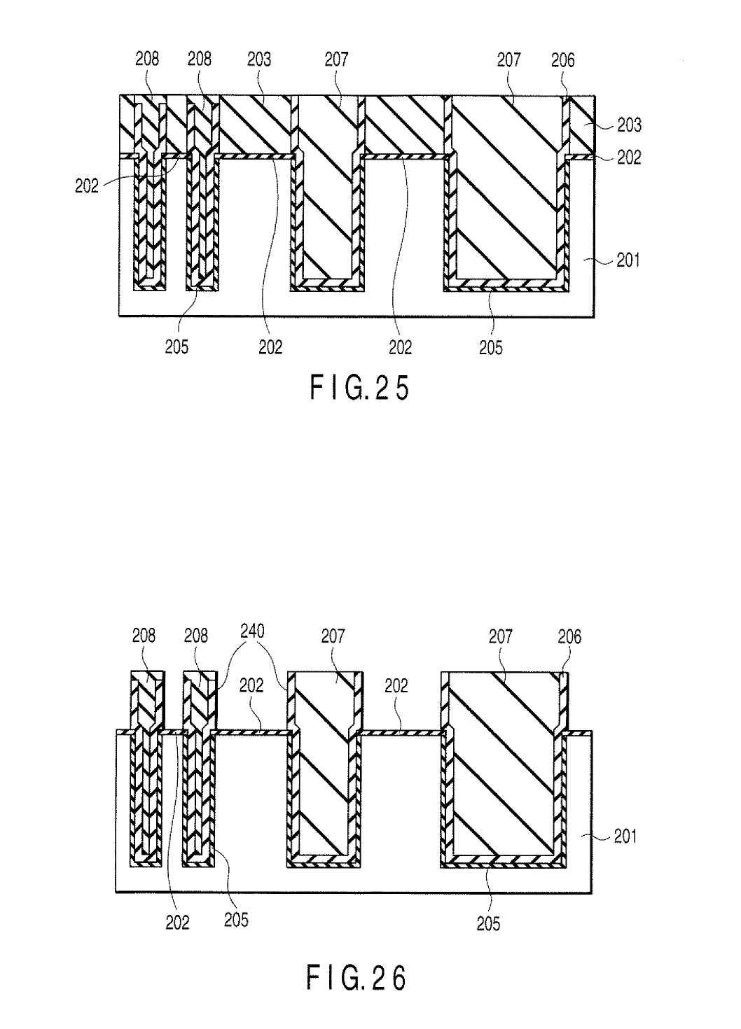

After this, as shown in FIG. 25, the HOP-CVD silicon oxide film 207, silicon oxide film 206 and condensed CVD film 208 are polished with the silicon nitride film 203 used as a stopper by use of the CMP technique. Thus, the chemical vapor condensation film 208 is left behind only in the isolation trenches 2041 and the HDP-CVD silicon oxide film 207 is left behind only in the isolation trenches 2042.

Next, as shown in FIG. 26, STI regions are formed by removing the silicon nitride film 203 by use of hot phosphoric acid. At this time, the top of the STI portions 240 is about 80 nm above the substrate surface.

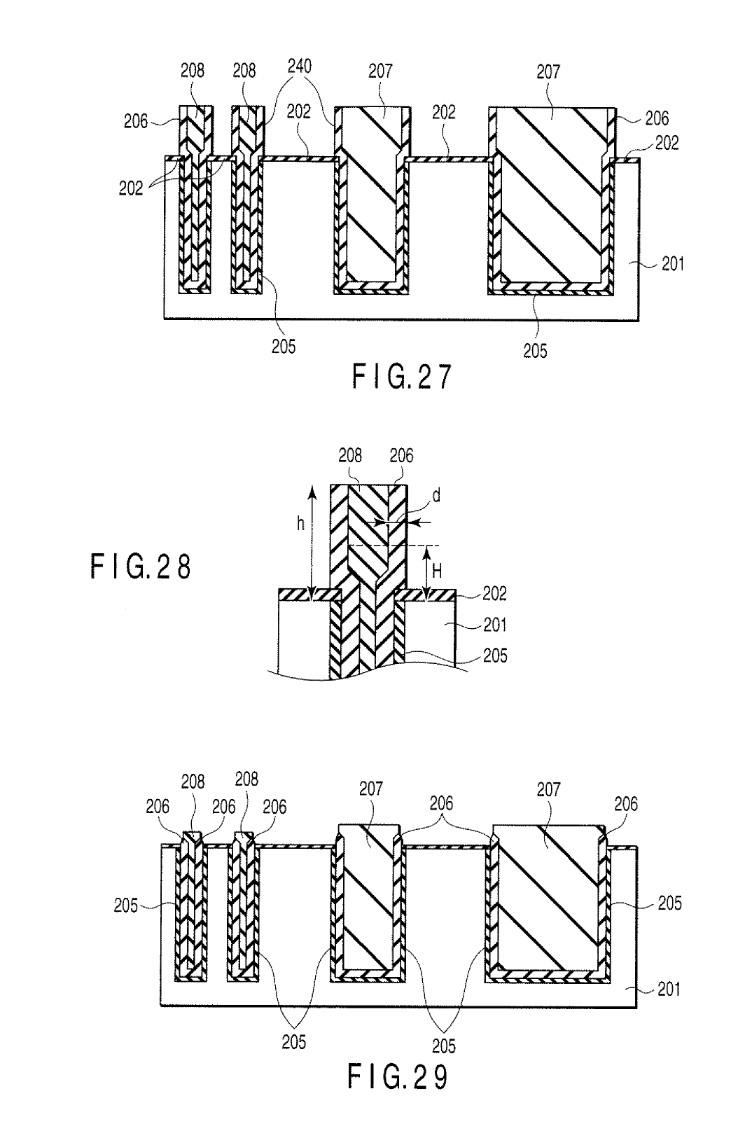

Then, as shown in FIG. 27, the height of the STI portions 240 is adjusted by use of the normal lithography technique and reactive ion etching technique.

After this, the buffer oxide film is removed and a multi-oxidation process is performed to form gate oxide films, but the drawing showing the intermediate process is omitted.

In this case, the ratio of the wet etching rates of the CVD silicon oxide film 206 and chemical vapor condensation film 208 with respect to a wet etching liquid used in the preprocess for the gate oxide films, that is, the ratio of (the wet etching rate of the chemical vapor condensation film 208/the wet etching rate of the silicon oxide film 206) is set to R. Further, as shown in FIG. 28, it is supposed that the film thickness of the CVD oxide film 206 of the side wall portion in the STI region of small width is set to d, the height of the chemical vapor condensation film 208 from the substrate 201 is set to h and the height of the finally formed STI region (chemical vapor condensation film 208) from the substrate 201 is set to H. Then, a preferable STI form having the STI structure of substantially the smooth upper portion and having no STI divot at the active area edge can be realized as shown in FIG. 29 after the wet etching process for the multi-oxide by setting the following expression.

h−H>dR

In the case of the present embodiment, it is necessary to set R smaller than 4 since h is 80 nm, H is 30 nm and d is 12 nm and this can be attained by use of buffered hydrofluoric acid of HF:NH₄F=1:15.

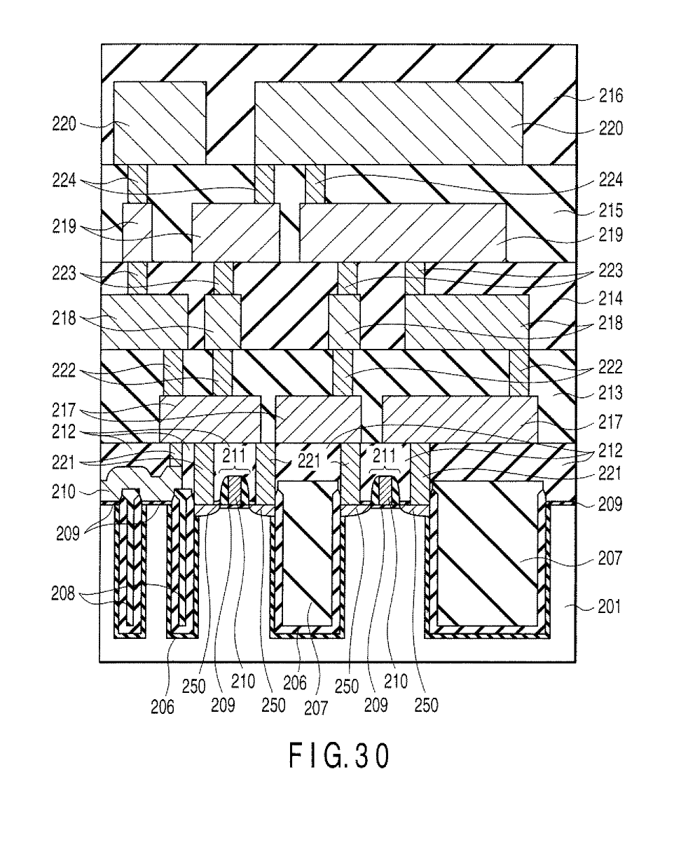

After this, as shown in FIG. 30, a silicon thermal oxynitride film 209 used as gate oxide films and a polysilicon film 210 used as gate electrodes are formed and processed by the heretofore known lithography technique and RIE technique and source/drain regions 250 and lightly doped drain (LDD) regions are formed by the known diffusion layer forming technique so as to form MOS transistors 211.

Further, a device with the final structure is formed by forming inter-level insulating films (PMD) 212, 213, 214, 215, 216 and a multi-layered wiring structure having wirings 217, 219, 219, 220 and contact plugs 221, 222, 223, 224 as shown in FIG. 30 although a detailed explanation of the process is omitted.

As described above, the STI region of small width and the STI region of large width can be separately formed without additionally using a lithography process by the manufacturing method of the semiconductor device of the present embodiment.

That is, the STI region of small width approximately 32 nm in the cell portion can be filled without causing voids and seams by use of a flowable insulating film. At the same time, the structure in which the STI region with the wide width in the peripheral circuit portion is filled only with an HDP-CVD silicon oxide film which is excellent in processing resistance can be realized.

Since the STI region with the large width mainly used as the peripheral circuit portion can be filled only with the HOP-CVD silicon oxide film, the STI region will not be influenced by strong stress caused when the STI region is filled with a flowable insulating film in the case of the STI region of narrow width in the cell portion. Therefore, it is possible to attain an advantage that problems of cracking of films and deviation in the transistor threshold voltage shift caused by the STI impurities can be solved.

Further, conventionally, in order to form a hybrid structure using both of an insulating film having fluidity at the film formation time and an HDP-CVD silicon oxide film, two CMP steps are required. Therefore, there occurs a problem that the number of steps is increased and the process margin is lowered due to increased complication of the process. However, in the present embodiment, it is sufficient to perform one CMP step and the process can be simplified.

In the present embodiment, the condensed CVD film is used as the insulating film having fluidity at the film formation time to fill the trenches used as the STI regions of small width, but an SOG film such as a hydrogen silsesquioxane (HSQ) film, polysilazane film or the like can be used as a filling material as in the case of the first embodiment.

### Third Embodiment

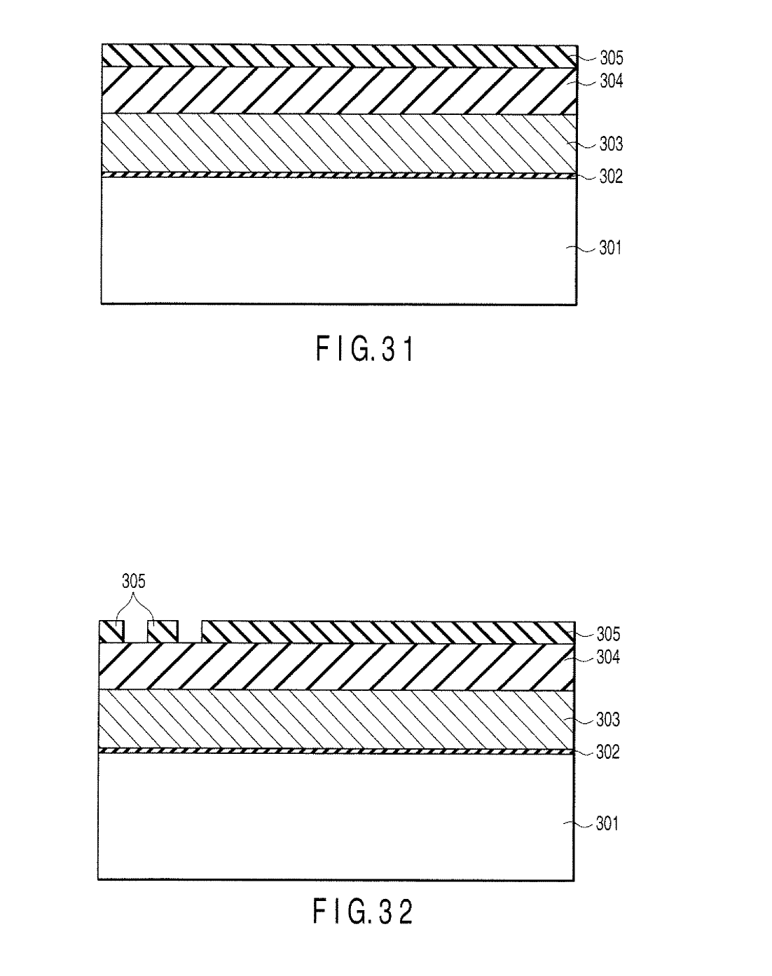

A manufacturing method of a semiconductor device according to a third embodiment of this invention is explained with reference to FIGS. 31 to 50.

The present embodiment is one example of a manufacturing method of a flash memory and, in this case, a gate insulating film and gate electrode film used as floating gates are previously formed on a semiconductor substrate and then STI of the cell portion are formed. After this, a silicon nitride film used as a barrier film which protects the cell portion is formed and then STI regions in a peripheral portion are formed.

First, as shown in FIG. 31, a silicon thermal oxynitride film 302 used as a gate insulating film is formed to a thickness of approximately 8 nm on a semiconductor substrate 301, a P-doped polysilicon film 303 used as floating gates is formed to a thickness of approximately 120 nm and a silicon nitride film 304 used as a polishing stopper for the CMP process is formed to a thickness of approximately 60 nm. Then, a CVD silicon oxide film 305 used as a mask for reactive ion etching (RIE) is formed on the entire surface of the silicon nitride film 304 (FIG. 31) and a photoresist film is further coated (not shown).

Next, the photoresist film is processed by use of the normal lithography technique and the silicon oxide film 305 is etched by the RIE process with the photoresist film used as a mask to form a hard mask 305 as shown in FIG. 32. At this time, the process for the silicon oxide film 30S is performed only for the cell portion. The remaining photoresist film is etched and removed by using a mixture of a hydrogen peroxide sulfuric acid mixture and ashing (FIG. 32).

Next, as shown in FIG. 33, the silicon nitride film 304, P-doped polysilicon film 303, silicon thermal oxynitride film 302 and semiconductor substrate 301 are sequentially processed by the RIE process using the hard mask 305 which is a CVD silicon oxide film.

Thus, isolation trenches 306 for STI with the etching depth of 220 nm are formed in the semiconductor substrate 301. The width of the isolation trench 306 for STI in the cell portion is 45 nm.

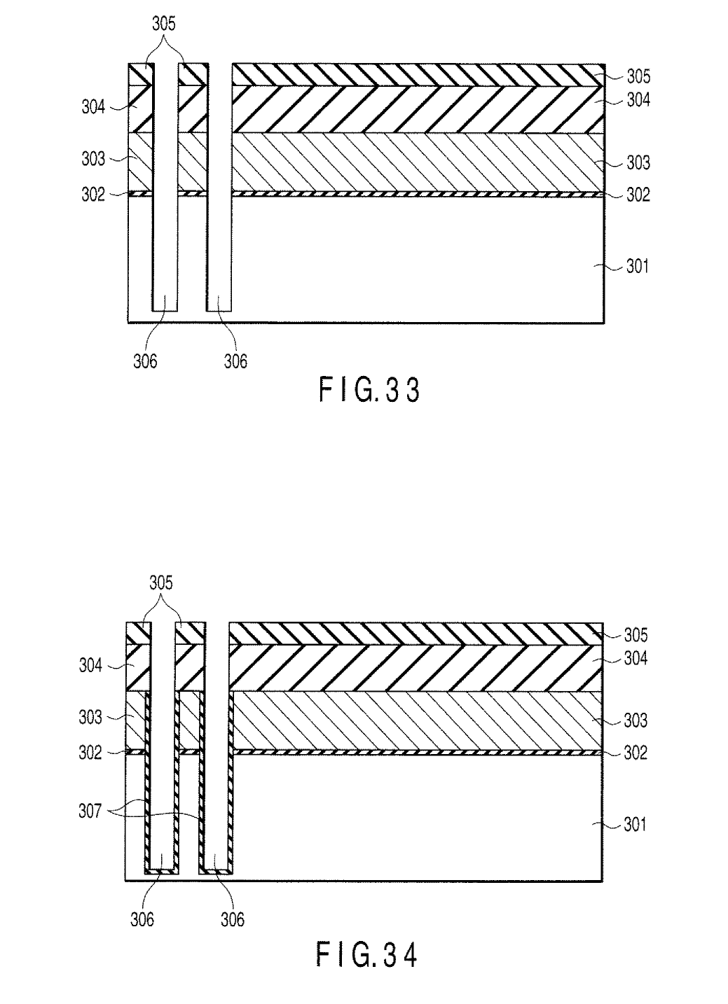

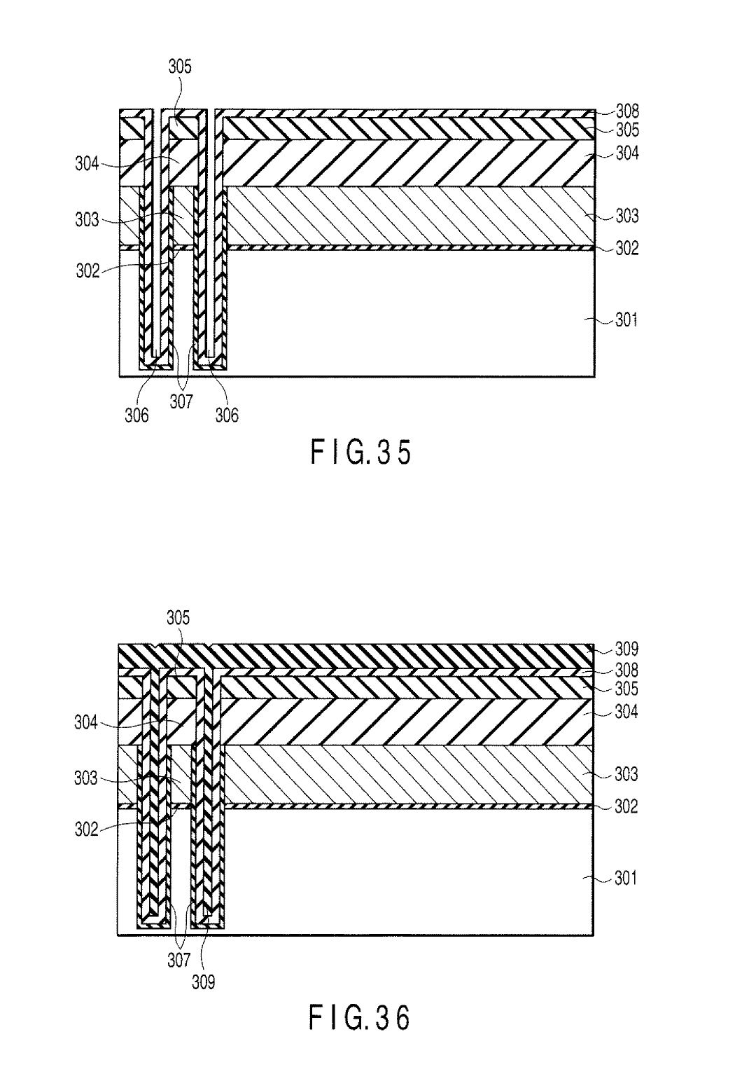

Next, as shown in FIG. 34, the inner surfaces of the isolation trenches 306 are thermally oxidized to form silicon thermal oxide films 307 of film thickness approximately 3 nm. Then, as shown in FIG. 35, a silicon oxide film 308 (first insulating film) which is a liner insulating film of film thickness approximately 15 nm is formed on the entire surface of the resultant semiconductor structure by use of the CVD method using silane and N₂O as source gases.

At this time, the silicon oxide film 308 is deposited between the resultant semiconductor structure and a polysilazane film which is to be formed in the succeeding step and has a function of enhancing the adhesion therebetween, and at the same time, acts as a barrier for impurities diffusion from the polysilazane film. Further, since the film thickness of the polysilazane film is required to be made larger if the silicon oxide film 306 is not formed, the process becomes difficult. Therefore, the silicon oxide film 308 has a role of minimizing the film volume of the polysilazane film.

Next, as shown in FIG. 36, a polysilazane film 309 is formed on the entire surface of the resultant semiconductor structure to fully fill the internal portions of the isolation trenches 306. The polysilazane film 309 is an SOG film which can fill the internal portions of the isolation trenches 306 without causing voids.

The polysilazane film 309 can be formed by the same method as explained in the first embodiment and a detailed explanation thereof is omitted. In the case of the present embodiment, the target coating film thickness is approximately 250 nm immediately after baking.

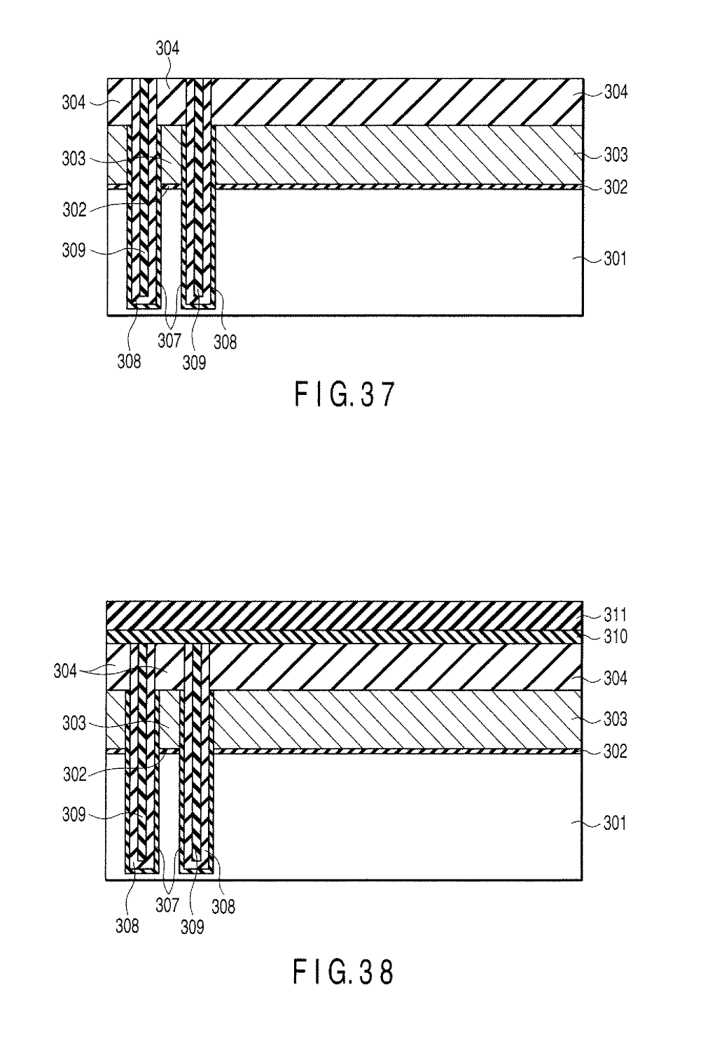

Tike the first embodiment, after the density of the polysilazane film 309 is enhanced by annealing in the inert gas atmosphere, the silicon oxide film 305, silicon oxide film 308 and polysilazane film 309 are polished by the CMP process with the silicon nitride film 304 used as a stopper as shown in FIG. 37. Thus, the polysilazane film 309 is left behind only in the isolation trenches 306.

Next, as shown in FIG. 38, a silicon nitride film 310 used as a barrier film is formed to a thickness of approximately 20 nm on the entire surface of the resultant semiconductor structure. Then, a CVD silicon oxide film 311 used as a mask for the reactive ion etching (RIE) process is formed on the entire surface of the silicon nitride film 310 (FIG. 38) and then a photoresist film is coated thereon (not shown).

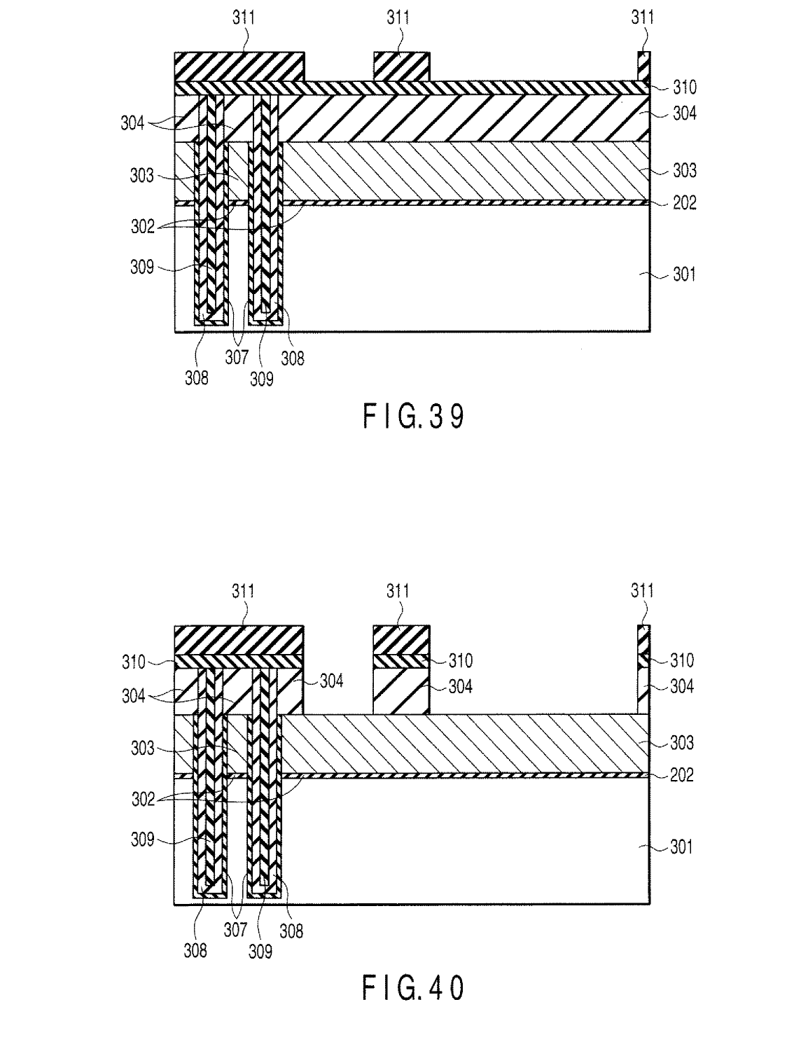

Next, the photoresist film is processed by the normal lithography technique and a hard mask 311 is formed by etching the silicon oxide film 311 by the RIE process with the photoresist film used as a mask as shown in FIG. 39. At this time, the etching process for the silicon oxide film 311 is performed to form an STI region with the wide width of 100 nm or more in a peripheral portion. The remaining photoresist film is etched and removed by using a mixture of a hydrogen peroxide sulfuric acid mixture and ashing (FIG. 39).

Next, as shown in FIG. 40, the silicon nitride films 310, 304 are etched by the RIE process using the hard mask 311 formed of a CVD silicon oxide film.

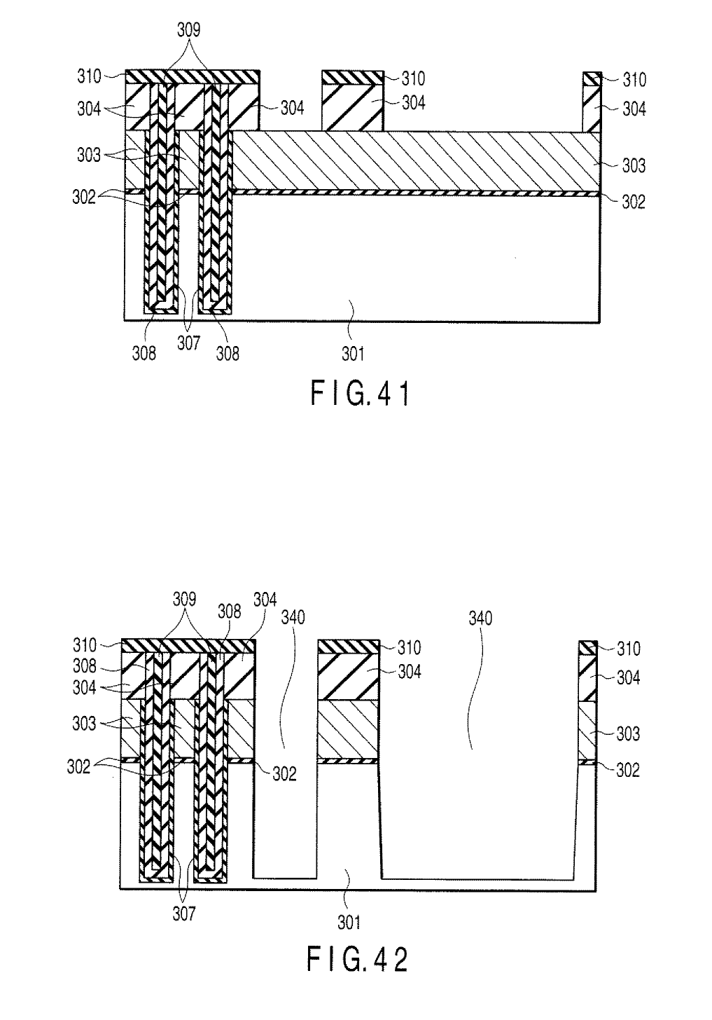

Then, as shown in FIG. 41, the hard mask 311 is removed by the wet etching process. Since the STI region in the cell portion is protected by the silicon nitride film 310, there occurs no problem of deformation, change in quality and the like.

After this, as shown in FIG. 42, the P-doped polysilicon film 303, silicon thermal oxynitride film 302 and semiconductor substrate 301 are sequentially etched with the silicon nitride films 310, 304 used as a mask.

Thus, isolation trenches 340 for STI with the etching depth of 220 nm are formed in the semiconductor substrate 301. The width of the isolation trench 340 for STI in the peripheral portion is 100 nm or more.

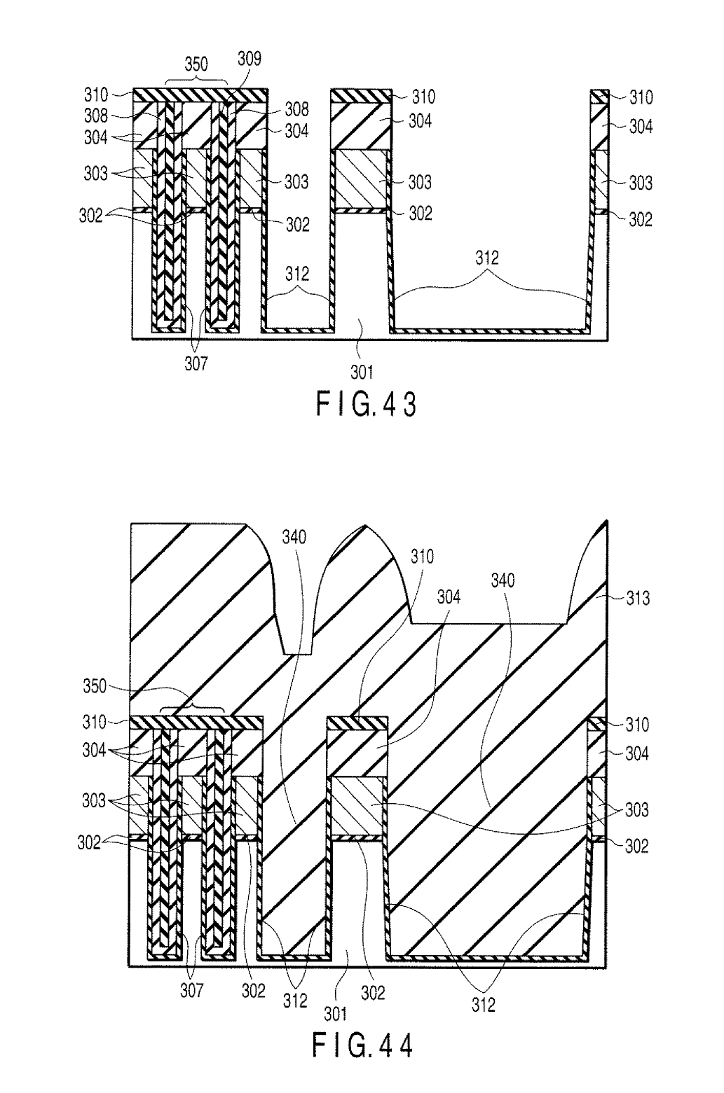

Next, as shown in FIG. 43, the inner surfaces of the isolation trenches 340 are thermally oxidized to form silicon thermal oxide films 312 of film thickness 3 nm. Since the cell portion 350 is protected by the silicon nitride film 310 which is a barrier film at this time, occurrence of bird's beak oxidation which is the wedge shape oxidation near the edge of the P-doped polysilicon film 303/the silicon thermal oxynitride film 302 interface caused by oxidant diffusion from the active area edge can be prevented.

Further, since the cell portion 350 is protected by the silicon nitride film 310, the film thickness of the silicon thermal oxide film 312 can be made different from the film thickness of the silicon thermal oxide film 307 of the cell portion 350.

Then, as shown in FIG. 44, an HDP-CVD silicon oxide film 313 (second insulating film) is formed to 500 nm on the entire surface of the substrate 301. The film forming condition is the same as that of the first embodiment. In the peripheral circuit portion and the like in the present embodiment, since an STI region which has a width less than 100 nm and is difficult to fill is not provided, the isolation trenches 340 for STI of width 100 nm or more in the peripheral circuit portion and the like can be fully filled with the HDP-CVD silicon oxide film 313.

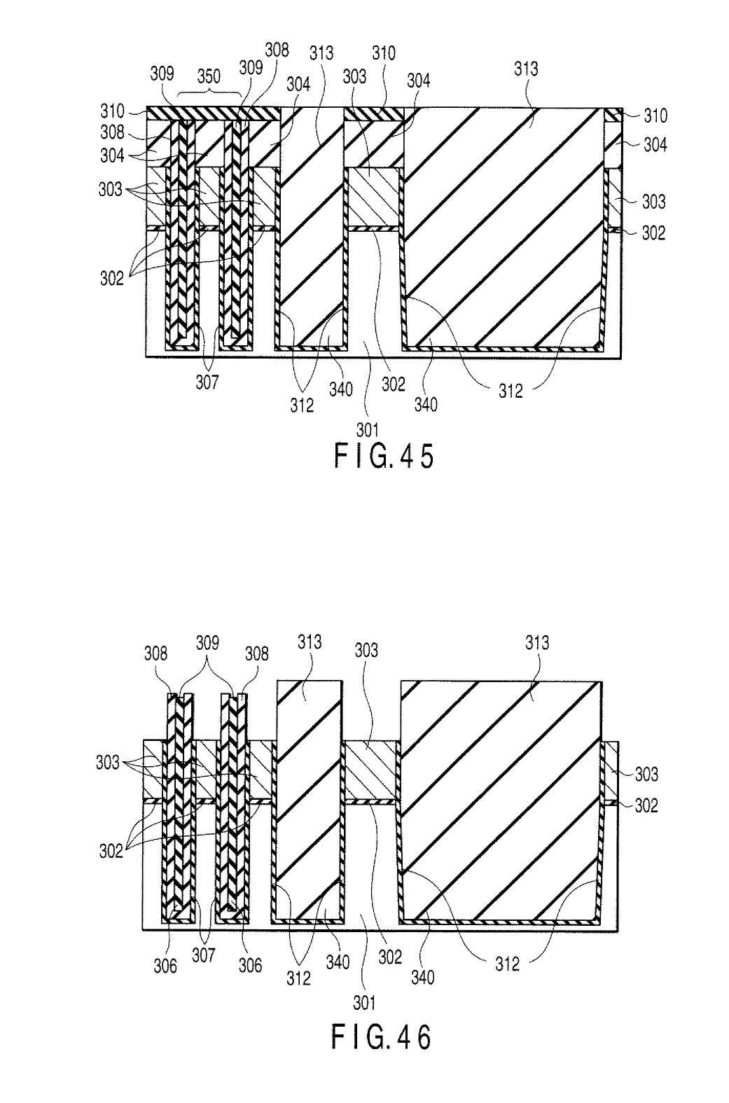

Next, as shown in FIG. 45, the HDP-CVD silicon oxide film 313 is polished by the CMP technique with the silicon nitride films 310, 304 used as a stopper and is left behind only in the isolation trenches 340.

Then, as shown in FIG. 46, the silicon nitride films 310, 304 are removed by use of hot phosphoric acid. At this time, the upper portions of the polysilazane films 309 are slightly recessed due to a difference in the etching rate in the hot phosphoric acid.

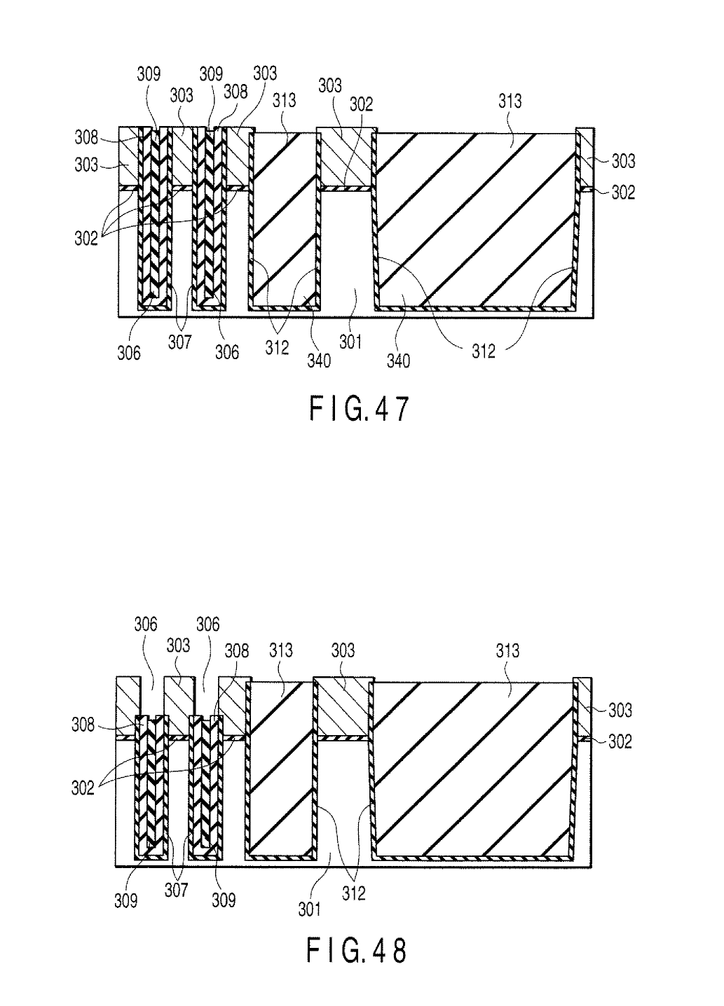

After this, as shown in FIG. 47, STI regions 306 of the cell portion and STI regions 340 of the peripheral circuit portion are formed by etching back the remaining filling insulating films (HDP-CVD silicon oxide film 313, silicon oxide film 308 and polysilazane films 309) by approximately 80 nm by a reactive ion etching process.

Further, as shown in FIG. 48, the internal portions of the isolation trenches 306 used as the STI regions of the cell portion are further etched back by approximately 40 nm by the heretofore known lithography technique and RIE technique.

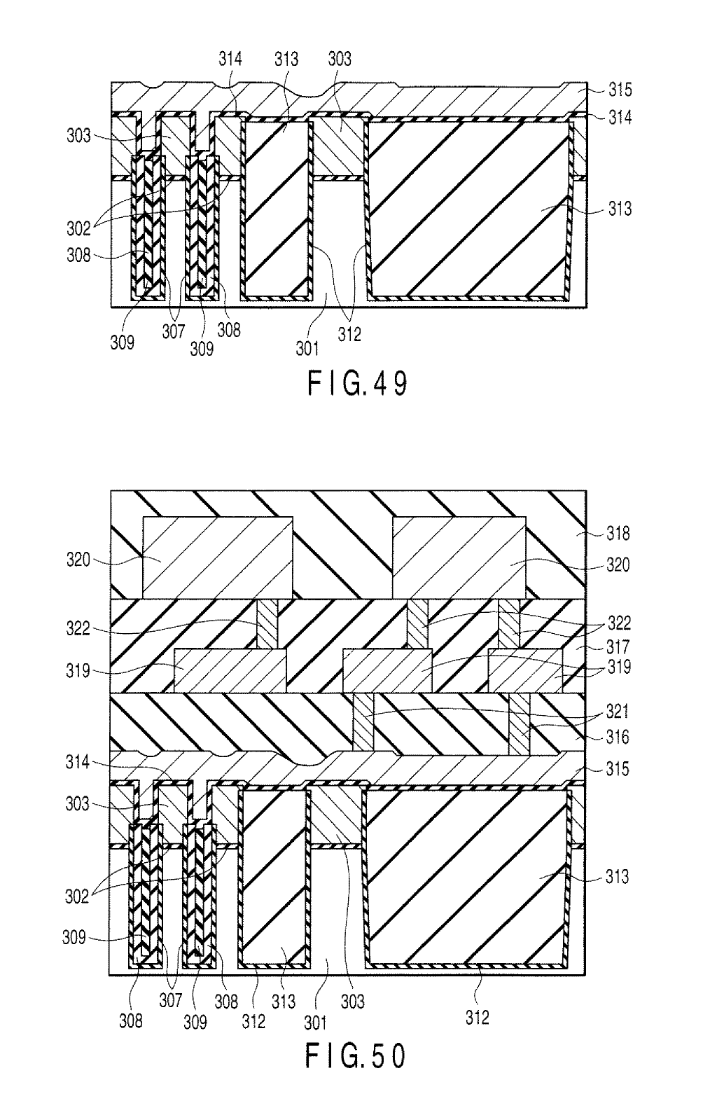

Next, as shown in FIG. 49, an ONO film 314 used as an electrode-electrode insulating film (IPD) is formed on the entire surface of the resultant semiconductor structure and a P-doped polysilicon film 315 used as control gate electrodes is formed thereon.

Then, the P-doped polysilicon film 315, ONO film 314 and P-doped polysilicon film 303 are sequentially processed by the known lithography technique and RIE technique to form control gates and floating gates (not shown).

After this, a device with the final structure is formed by forming inter-level insulating films (PMD) 316, 317, 318 and a multi-layered wiring structure having wirings 319, 320 and contact plugs 321, 322 as shown in FIG. 50 although a detailed explanation of the process is omitted.

As described above, the cell portion and peripheral portion can be separately formed by the manufacturing method of the semiconductor device of the present embodiment. That is, the cell portion can be filled with a film having a good filling property, for example, a polysilazane film, and the peripheral circuit portion is filled with a film having excellent processing resistance, for example, an HDP-CVD silicon oxide film. Thus, the filling insulating films can be separately and adequately used.

Since the STI region of wide width mainly used as the peripheral circuit portion can be filled only with the HDP-CVD silicon oxide film, the STI region will not be influenced by strong stress caused when the STI region is filled with a filling insulating film having fluidity during the film formation as in the case of the STI region of small width in the cell portion. Therefore, it is possible to attain an advantage that problems of film cracking and the transistor threshold voltage shift due to the STI impurities can be solved.

Further, by forming the barrier film on the cell portion, the STI region in the cell portion can be prevented from deformation or deterioration during the peripheral circuit STI formation. For example, the problem that the completed STI region in the cell portion is etched by the etching process for the peripheral circuit portion or the cell portion is oxidized at the time of forming the STI region in the peripheral circuit portion can be prevented.

The wet etching process for the peripheral circuit portion can be freely performed by using the silicon nitride film as the barrier film as in the present embodiment. Further, the cell portion can be prevented from being oxidized by oxidation of the peripheral circuit portion.

In the present embodiment, the polysilazane film is used as the insulating film which has fluidity during the film formation and with which the trenches of the STI regions of small width are to be filled, but the STI trenches of small width can be filled with a different type of SOG film, for example, a hydrogen silsesquioxane (HSQ) film ((HSiO_{3/2})ₙ, where n is an integer) or chemical vapor condensation.

### Fourth Embodiment

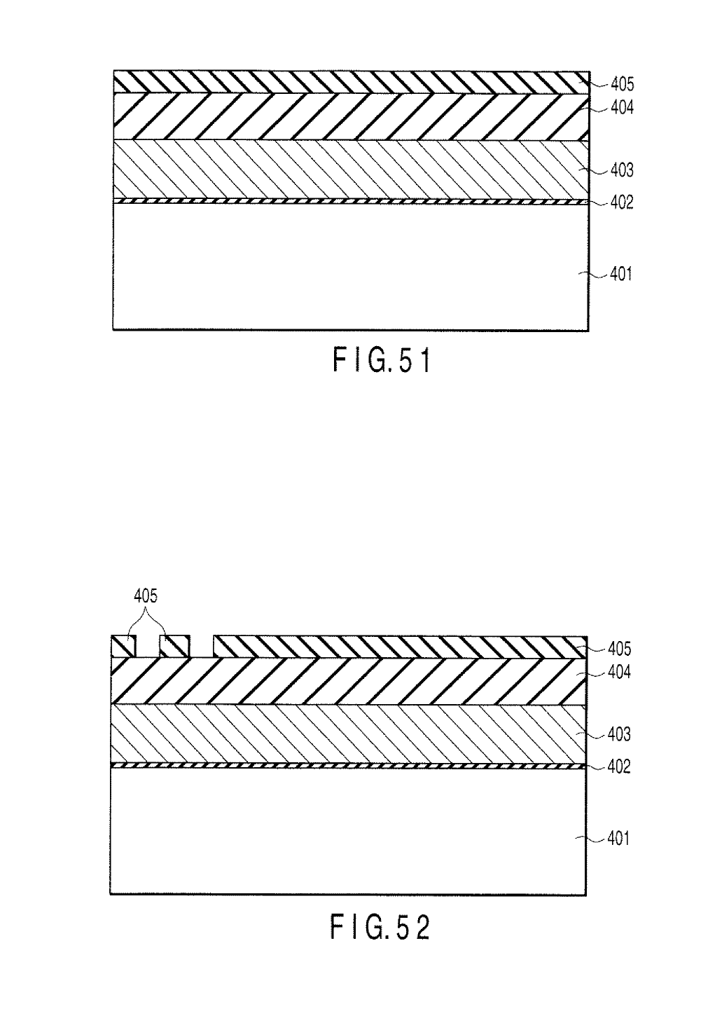

A manufacturing method of a semiconductor device according to a fourth embodiment of this invention is explained with reference to FIGS. 51 to 68.

Like the third embodiment, the present embodiment is one example of a manufacturing method of a flash memory and, in this case, STI regions of a cell portion are first formed when STI regions are formed. Then, a silicon oxide film which can also be used as a hard mask as a barrier film to protect the cell portion and STI regions of a peripheral portion are formed.

First as shown in FIG. 51, a silicon thermal oxynitride film 402 used as a gate insulating film is formed to a thickness of approximately 8 nm on a semiconductor substrate 401, a P-doped polysilicon film 403 used as floating gates is formed to a thickness of approximately 120 nm and a silicon nitride film 404 used as a polishing stopper for a CMP process is formed to a thickness of approximately 60 nm. Then, a CVD silicon oxide film 405 used as a mask for a reactive ion etching (RIE) is formed on the entire surface of the silicon nitride film 404 (FIG. 51) and a photoresist film is coated thereon (not shown).

Next, the photoresist film is processed by the normal lithography technique and the silicon oxide film 405 is etched by the RIE process with the photoresist film used as a mask to form a hard mask 405 as shown in FIG. 52. At this time, the process for etching the silicon oxide film 405 is performed only for the cell portion. The remaining photoresist film is etched and removed by means of a mixture of a hydrogen peroxide sulfuric acid mixture and ashing (FIG. 52).

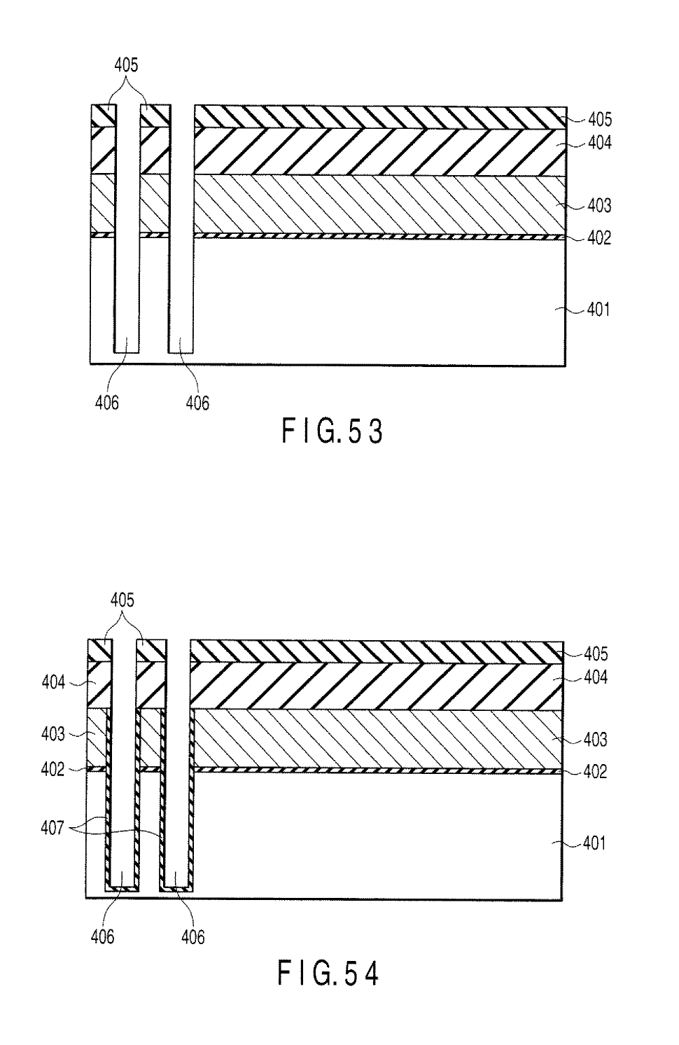

Then, as shown in FIG. 53, the silicon nitride film 404, P-doped polysilicon film 403, silicon thermal oxynitride film 402 and semiconductor substrate 401 are sequentially processed by the RIE process using the hard mask 405 formed of the CVD silicon oxide film.

As a result, isolation trenches 406 used as STI regions with the etching depth of 220 nm in the cell portion are formed in the semiconductor substrate 401. The width of the isolation trench 406 is set to 45 nm.

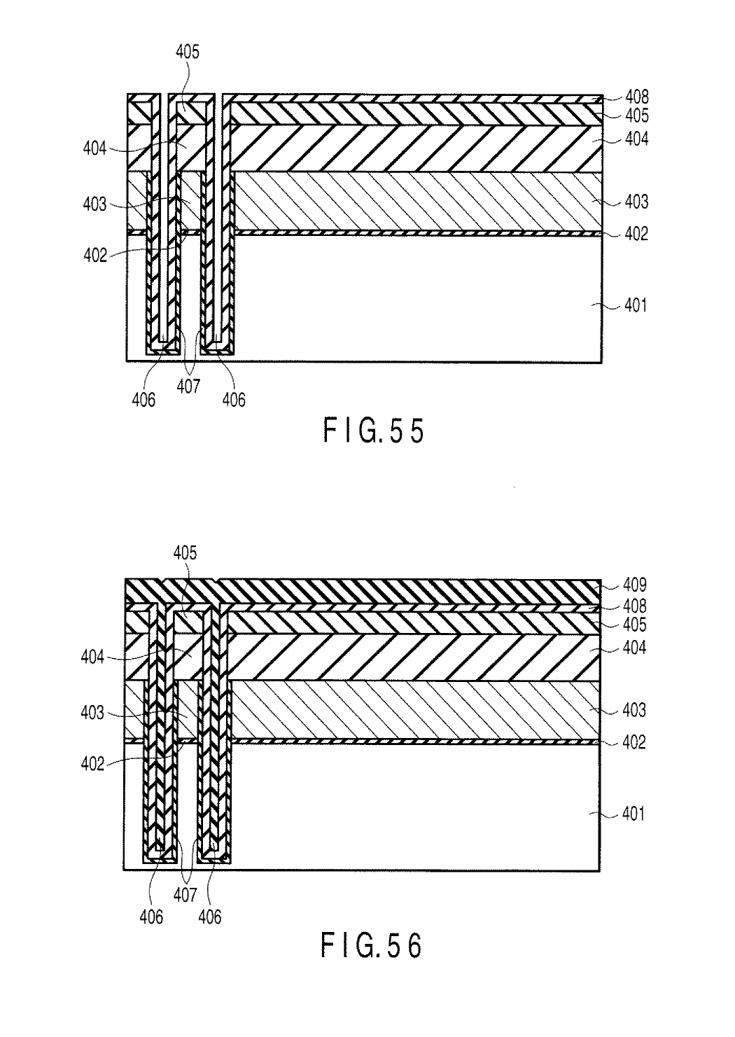

After this, as shown in FIG. 54, the inner surfaces of the isolation trenches 406 are thermally oxidized to form silicon thermal oxide films 407 of film thickness 3 nm. Further, as shown in FIG. 55, a is silicon oxide film 408 (first insulating film) which is a liner insulating film of film thickness 15 nm is formed on the entire surface of the resultant semiconductor structure by means of the CVD method using silane and N₂O as source gases. The function and purpose of the silicon oxide film 408 are the same as those of the silicon oxide film 308 explained in the third embodiment.

Next, as shown in FIG. 56, a polysilazane film 409 is formed on the entire surface of the resultant semiconductor structure to fully fill the isolation trenches 406. The polysilazane film 409 is an SOG film having fluidity at the film formation time, as described previously, and can fill the isolation trenches 406 without causing voids.

The method for forming the polysilazane film 409 is the same as that of the first and third embodiments. That is, a perhydropolysilazane solution is coated on the surface of the semiconductor substrate 401 by a spin coating method and then C, N remaining in the film are removed with steam-oxidation process after an organic solvent is removed by baking. Further, the density of the polysilazane film 409 is enhanced by performing the annealing process in the inert gas atmosphere at 800 to 1000° C.

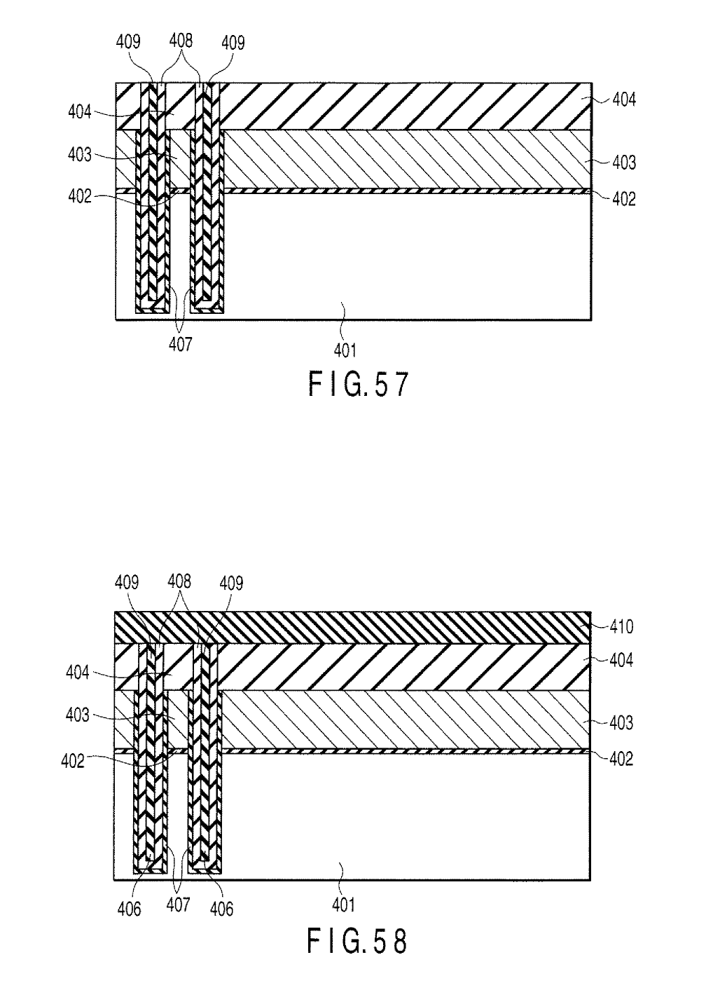

Next, as shown in FIG. 57, the silicon oxide film 405, silicon oxide film 408 and polysilazane film 409 are polished by the CMP technique with the silicon nitride film 404 used as a stopper. Thus, the polysilazane film 409 is left behind only in the isolation trenches 406.

Next, as shown in FIG. 58, a silicon oxide film 410 used as a barrier film and hard mask is formed to a thickness of 100 nm on the entire surface of the resultant semiconductor structure by the LPCVD method using TEOS as a source gas (FIG. 58) and then a photoresist film is coated on the entire surface of the silicon oxide film 410 (not shown).

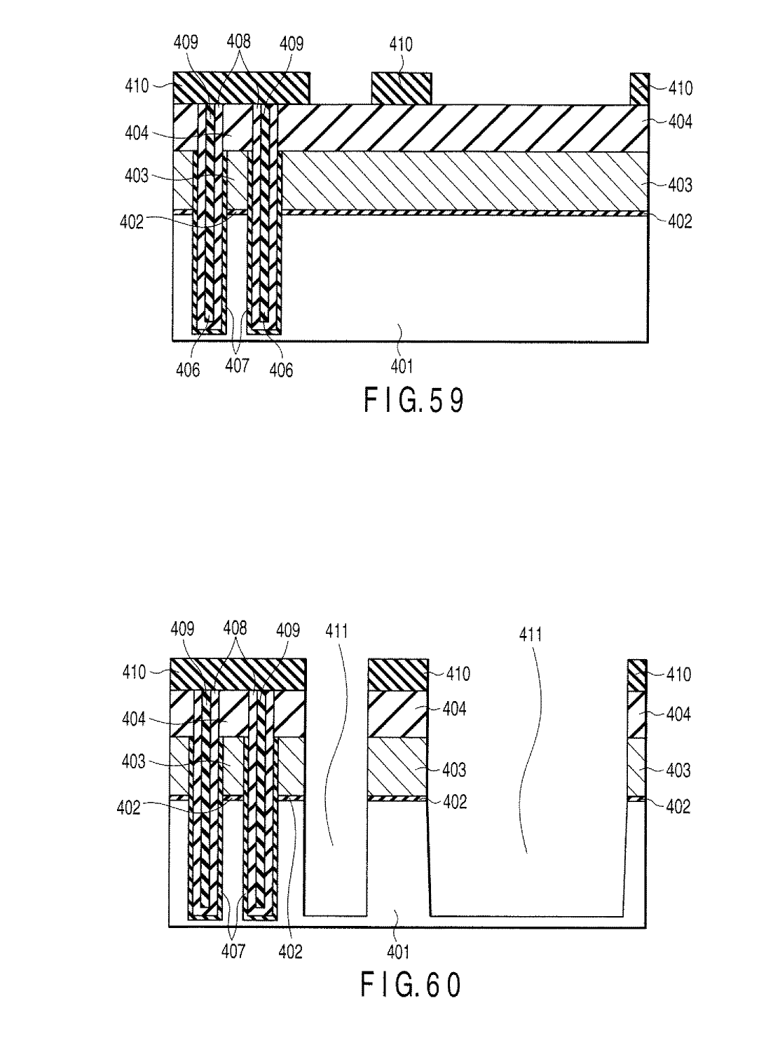

Next, the photoresist film is processed by the normal lithography technique and the silicon oxide film 410 is etched by the RIE process with the photoresist film used as a mask to form a hard mask 410 as shown in FIG. 59. At this time, the etching process for the silicon oxide film 410 is performed to form STI regions with the width of 100 nm or more in the peripheral portion. The photoresist film is etched and removed by using a mixture of a hydrogen peroxide sulfuric acid mixture and ashing (FIG. 59).

Next, as shown in FIG. 60, the silicon nitride film 404, P-doped polysilicon film 403, silicon thermal oxynitride film 402 and semiconductor substrate 401 are sequentially processed by the RIE process by using the hard mask 410 formed of the CVD silicon oxide film.

Thus, isolation trenches 411 for STI with the etching depth of 220 nm are formed in the semiconductor substrate 401. The width of the isolation trench 411 for STI in the peripheral circuit portion is 100 nm or more.

Next, as shown in FIG. 61, the inner surfaces of the isolation trenches 411 are thermally oxidized to form silicon thermal oxide films 412 of film thickness 3 nm. At this time, in the present embodiment, since the cell portion 450 is protected by the thick silicon oxide film 410 which is a barrier film, occurrence of bird's beak oxidation can be prevented.

Further, since the cell portion 450 is protected by the silicon oxide film 410, the film thickness of the silicon thermal oxide film 412 can be made different from the film thickness of the silicon thermal oxide film 407 of the cell portion 450.

Then, as shown in FIG. 62, an HDP-CVD silicon oxide film 413 (second insulating film) is formed to 500 nm on the entire surface of the substrate 401. The film forming condition is the same as that of the first embodiment. In the peripheral circuit portion and the like in the present embodiment, since an STI region which has a width less than 100 nm and is difficult to fill is not provided, the isolation trenches 411 for STI of width 100 nm or more in the peripheral circuit portion and the like can be fully filled with the HDP-CVD silicon oxide film 413.

If the HDP-CVD silicon oxide film 413 is formed in a good gap-fill conditions there occurs a possibility of the problem that the top surface of the cell portion 450 may be eroded by sputtering or the cell active area may be oxidized. However, in the present embodiment, since the cell portion 450 is protected by the barrier film 410 formed of the thick silicon oxide film, the above problem will not occur.

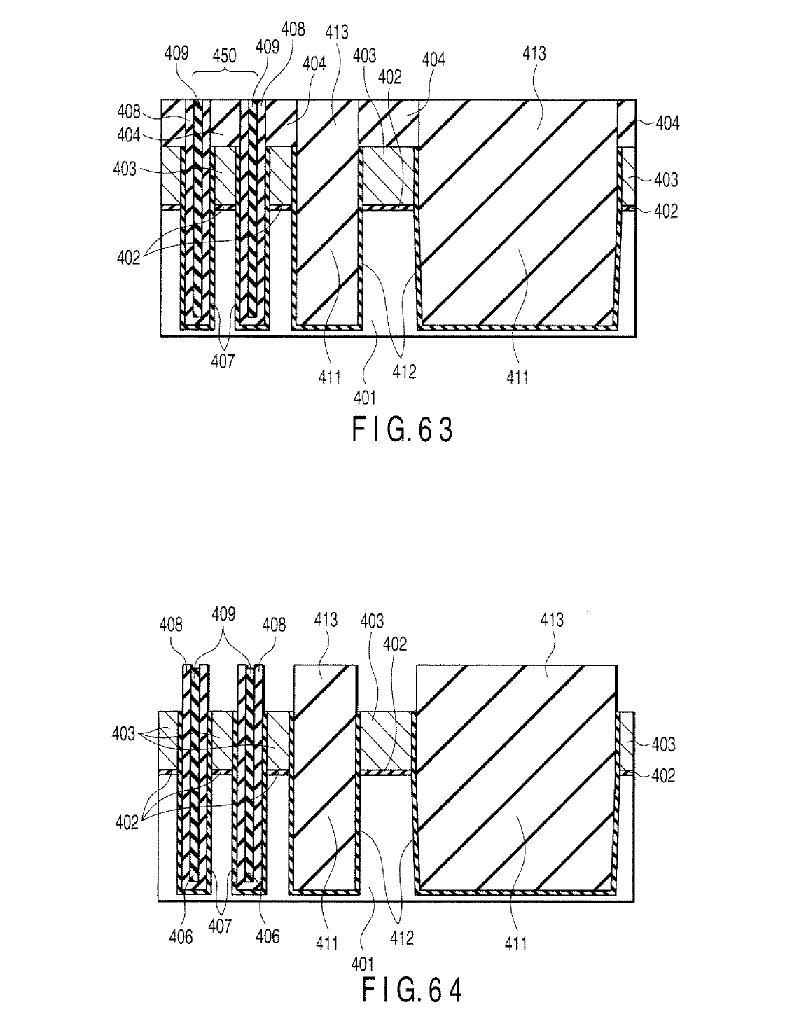

Next, as shown in FIG. 63, the silicon oxide film 410 and HDP-CVD silicon oxide film 413 are polished by the CMP technique with the silicon nitride film 404 used as a stopper and the HDP-CVD silicon oxide film 413 is left behind only in the isolation trenches 411.

Then, as shown in FIG. 64, the silicon nitride film 404 is removed by means of hot phosphoric acid. At this time, the upper portions of the polysilazane films 409 are slightly depressed due to a difference in the etching rate in the hot phosphoric acid.

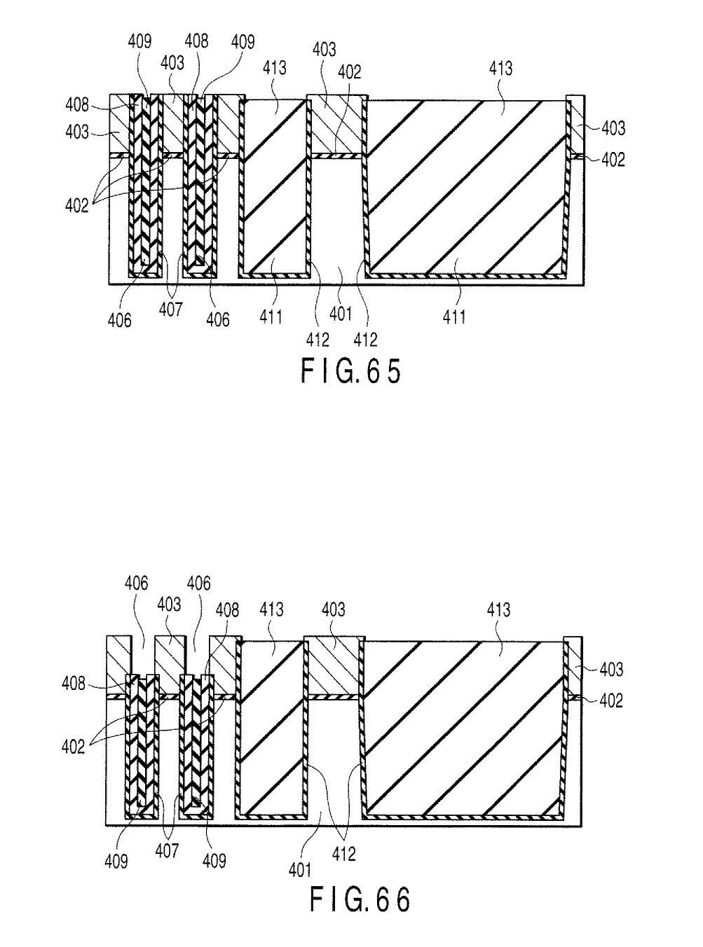

After this, as shown in FIG. 65, STI regions 406 of the cell portion and STI regions 411 of the peripheral circuit portion are formed by etching back the remaining filling insulating films (HDP-CVD silicon oxide films 413, silicon oxide films 408 and polysilazane films 409) by approximately 60 nm by a reactive ion etching process.

Further, as shown in FIG. 66, the internal portions of the isolation trenches 406 used as the STI regions of the cell portion are further etched back by approximately 40 nm by the heretofore known lithography technique and RIE technique.

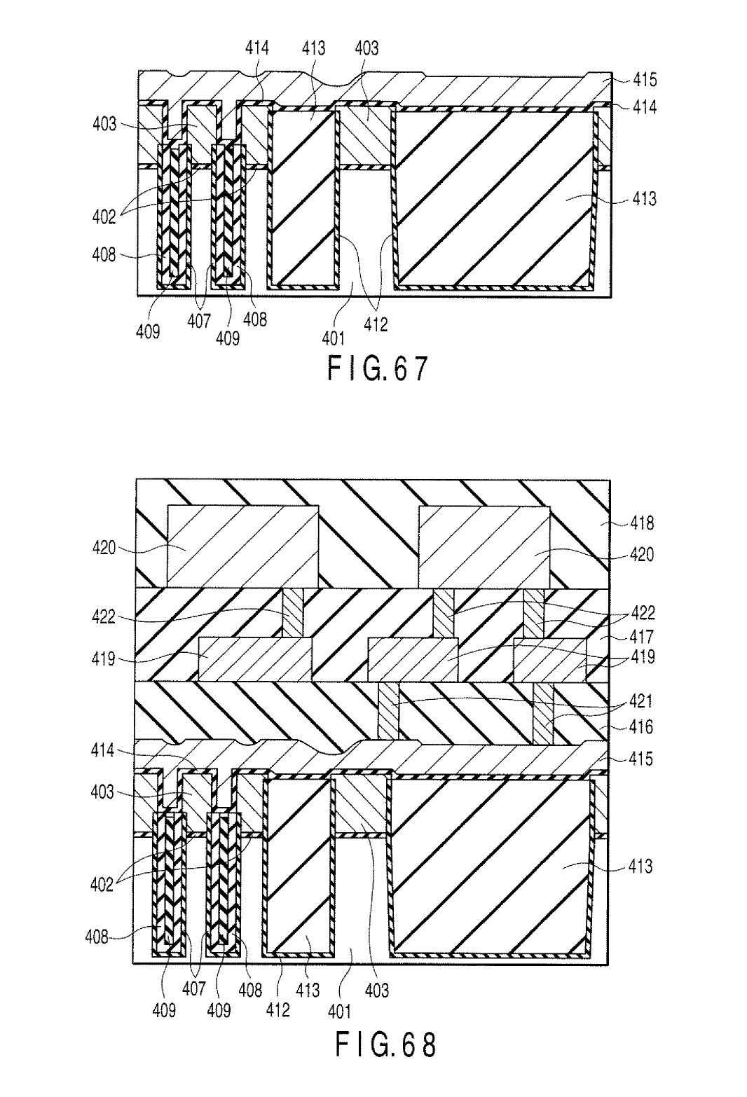

Next, as shown in FIG. 67, an ONO film 414 used as an electrode-electrode insulating film (IPD) is formed on the entire surface of the resultant semiconductor structure and a P-doped polysilicon film 415 used as control gate electrodes is formed thereon.

Then, the P-doped polysilicon film 415, ONO film 414 and P-doped polysilicon film 403 are sequentially processed by the known lithography technique and RIE technique to form control gates and floating gates (not shown).

After this, a device with the final structure is formed by forming inter-level dielectric films (ILD) 416, 417, 418 and a multi-layered wiring structure having wirings 419, 420 and contact plugs 421, 422 as shown in FIG. 68 although a detailed explanation of the process is omitted.

As described above, the cell portion and peripheral portion can be separately formed by the manufacturing method of the semiconductor device of the present embodiment. That is, the cell portion can be filled with a film having a good filling property, for example, a polysilazane film, and the peripheral circuit portion is filled with a film having excellent processing resistance, for example, an HDP-CVD silicon oxide film. Thus the filling insulating films can be separately and adequately used.

Since the STI region of wide width mainly used as the peripheral circuit portion can be filled only with the HDP-CVD silicon oxide film, the STI region will not be influenced by strong stress caused when the STI region is filled with a flowable insulating film. Therefore, it is possible to attain an advantage that problems of film cracking and the transistor threshold voltages shift caused by STI impurities can be solved.

Further, by forming the barrier film on the cell portion, the STI region in the cell portion can be prevented from being deformation or deterioration during the peripheral circuit STI formation. For example, it is possible to prevent the problem that the completed cell STI is eroded by the etching process for the peripheral circuit portion or the cell active area is oxidized during the peripheral circuit STI formation.

Further, the cell portion can be protected, as in the case where the silicon nitride film is used, by using the thick silicon oxide film as the barrier film as in the present embodiment. The silicon oxide film can also be used as a hard mask when the peripheral circuit portion is processed.

In the present embodiment, the polysilazane film is used as the insulating film which has fluidity at the film formation time and with which the trenches of the STI regions of small width are to be filled, but the trenches for STI of narrow width can be filled with a different type of SOG film, for example, a hydrogen silsesquioxane (HSQ) film ((HSiO_{3/2})ₙ, where n is an integer) or chemical vapor condensation film.

### Fifth Embodiment

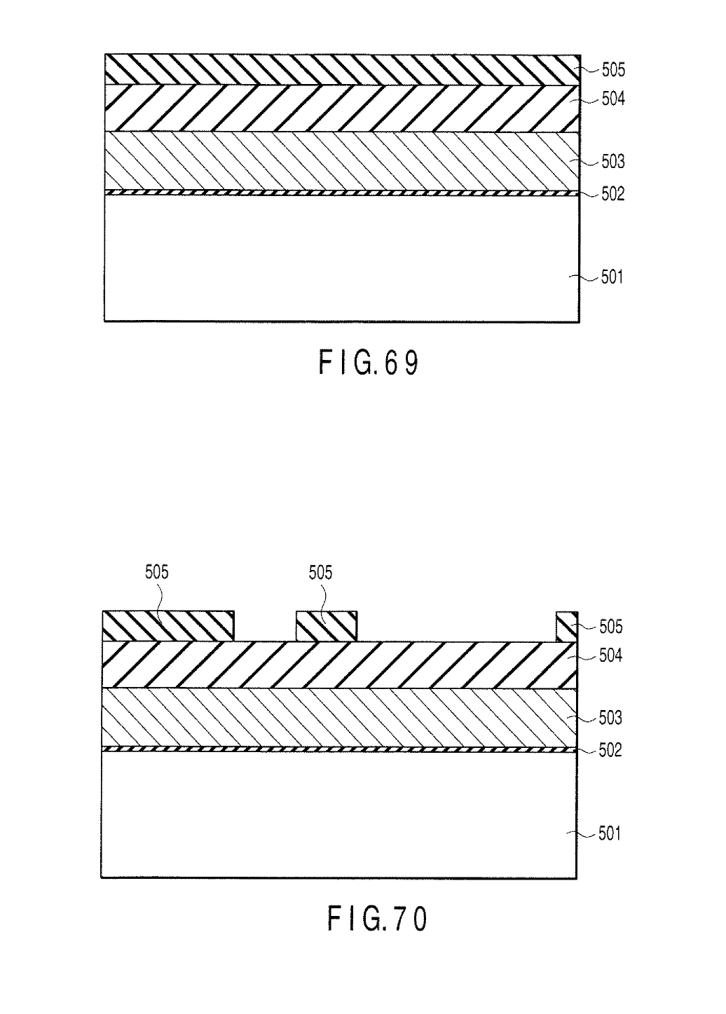

A manufacturing method of a semiconductor device according to a fifth embodiment of this invention is explained with reference to FIGS. 69 to 86.

Like the third and fourth embodiments, the present embodiment is one example of a manufacturing method of a flash memory and, in this case, STI regions of a peripheral portion filled with an HDP silicon oxide film are first formed when STI regions are formed. Then, STI regions of a cell portion are formed.

First as shown in FIG. 69, a silicon thermal oxynitride film 502 used as a gate insulating film is formed to a thickness of approximately 8 nm on a semiconductor substrate 501, a P-doped polysilicon film 503 used as floating gates is formed to a thickness of approximately 120 nm and a silicon nitride film 504 used as a polishing stopper for a CMP process is formed to a thickness of approximately 60 nm. Then, a CVD silicon oxide film 505 used as a mask for a reactive ion etching (RIE) process is formed on the entire surface of the silicon nitride film 504 (FIG. 69) and a photoresist film is coated thereon (not shown).

Next, the photoresist film is processed by the normal lithography technique and the silicon oxide film 505 is etched by the RIE process with the photoresist film used as a mask to form a hard mask 505 as shown in FIG. 70. The etching process for the silicon oxide film 505 is performed for the STI region with the width of 100 nm or more in the peripheral portion. The remaining photoresist film is etched and removed by use of a mixture of a hydrogen peroxide sulfuric acid mixture and ashing (FIG. 70).

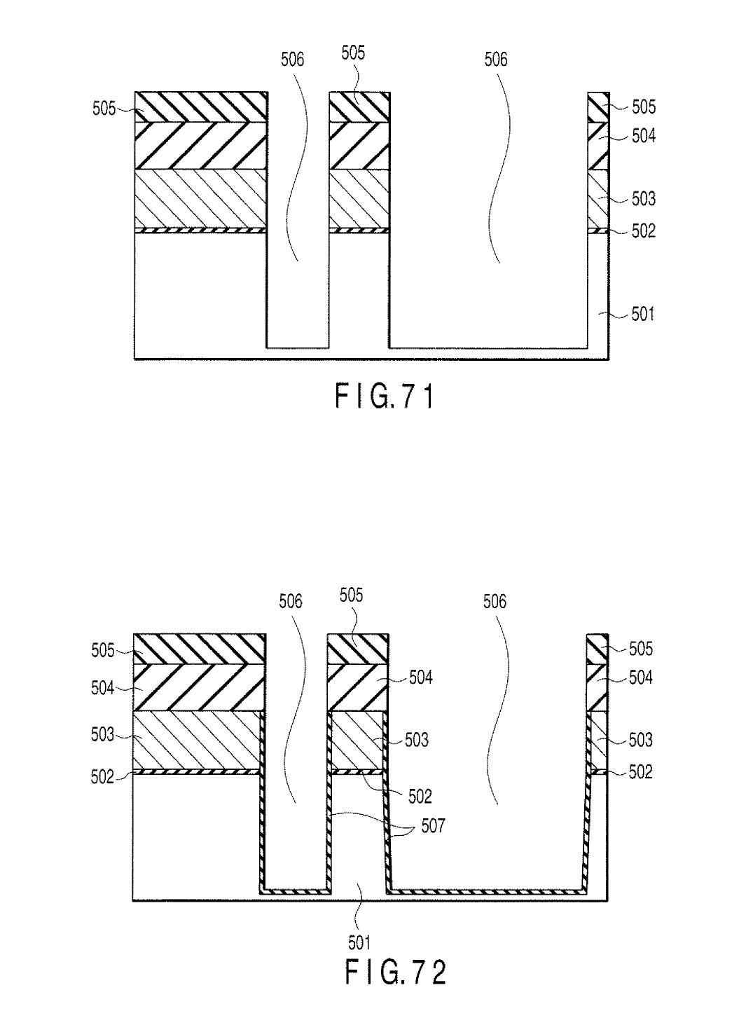

Then, as shown in FIG. 71, the silicon nitride film 504, P-doped polysilicon film 503, silicon thermal oxynitride film 502 and semiconductor substrate 501 are sequentially etched by the RIE process using the hard mask 505 formed of the CVD silicon oxide film.

As a result, isolation trenches 506 used as STI regions with the etching depth of 220 nm are formed in the semiconductor substrate 501. The width of the isolation trench 506 used as the STI region of the peripheral portion is set to 100 nm or more.

After this, as shown in FIG. 72, the inner surfaces of the isolation trenches 506 are thermally oxidized to form silicon thermal oxide films 507 of film thickness approximately 3 nm.

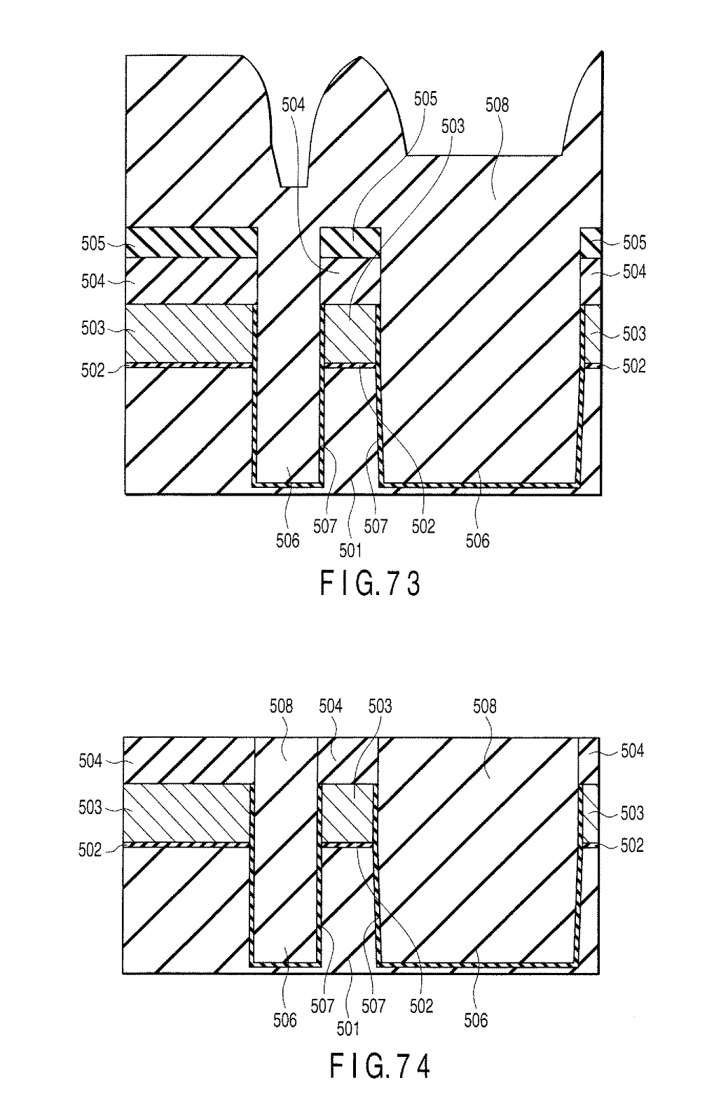

Further, as shown in FIG. 73, an HDP-CVD silicon oxide film 508 (second insulating film) is formed to a thickness of approximately 500 nm on the entire surface of the resultant semiconductor structure. The film forming condition is the same as that of the first embodiment. In the peripheral circuit portion of the present embodiment, since an STI region whose width is less than 100 nm and which is difficult to fill is not provided, the isolation trenches 506 used as the STI regions of width 100 nm or more in the peripheral circuit portion and the like are fully filled with the HDP-CVD silicon oxide film 508.

When the process for forming the HDP-CVD silicon oxide film 508 is performed in a good filling condition (the amount of sputtering components becomes larger with respect to that of deposition components), a problem that the upper portion of the cell portion is partly removed occurs in some cases. However, in the present embodiment, since the cell portion is not yet processed at this time point, the above problem does not occur.

Then, as shown in FIG. 74, the silicon oxide film 505 and HDP-CVD silicon oxide film 508 are polished with the silicon nitride film 504 used as a stopper by the CMP technique to leave HDP-CVD silicon oxide films 508 only in the isolation trenches 506.

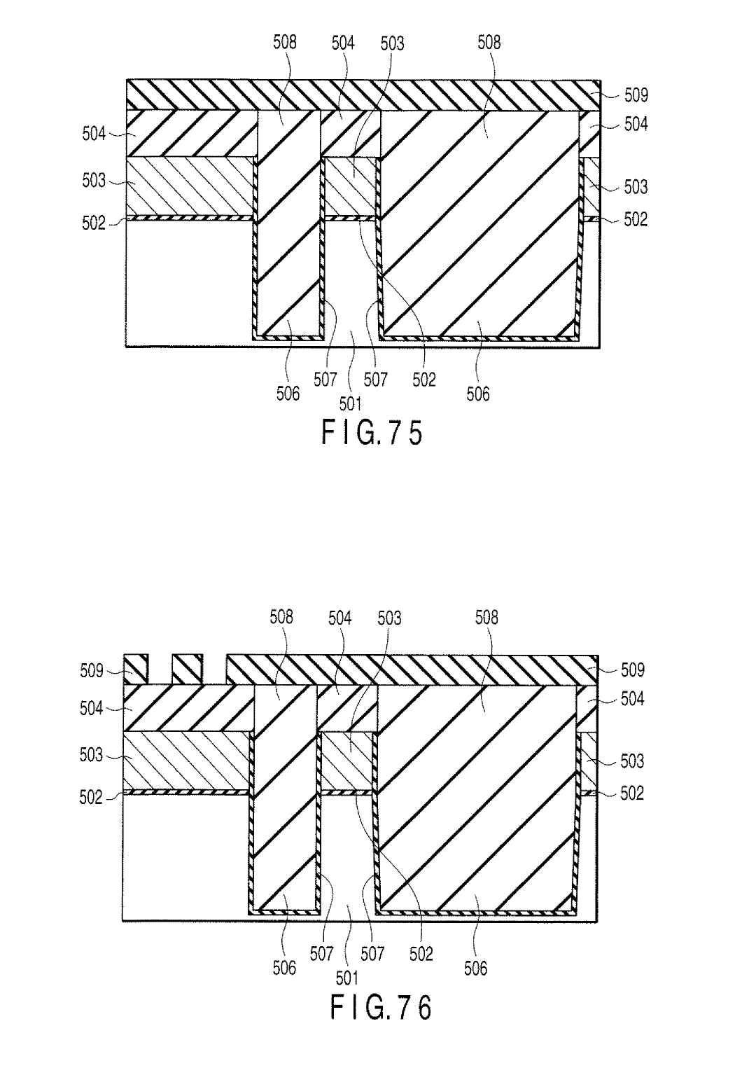

Next, as shown in FIG. 75, a CVD silicon oxide film 509 used as a mask for a reactive ion etching (RIE) process is formed on the entire surface of the resultant semiconductor structure and then a photoresist film is coated thereon (not shown).

After this, the photoresist film is processed by the normal lithography technique and the silicon oxide film 509 is etched by the RIE process with the photoresist film used as a mask to form a hard mask 509 as shown in FIG. 76. The process for the silicon oxide film 509 is performed only for the cell portion. The remaining photoresist film is etched and removed by using a mixture of a hydrogen peroxide sulfuric acid mixture and ashing (FIG. 76).

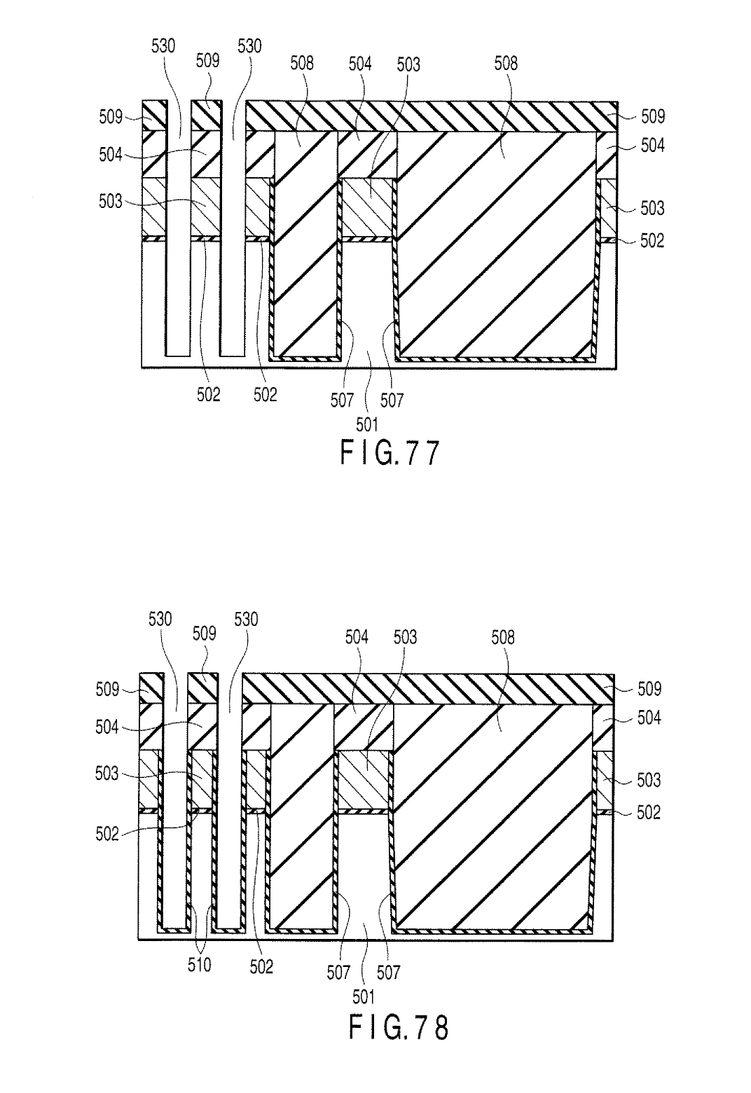

Next, as shown in FIG. 77, the silicon nitride film 504, P-doped polysilicon film 503, silicon thermal oxynitride film 502 and semiconductor substrate 501 are sequentially processed by the RIE process using the hard mask 509 formed of the CVD silicon oxide film.

Thus, isolation trenches 530 used as STI regions with the etching depth of 220 nm in the cell portion are formed in the semiconductor substrate 501. The width of the isolation trench 530 is 45 nm.

Next, as shown in FIG. 78, the inner surfaces of the isolation trenches 530 are thermally oxidized to form silicon thermal oxide films 510 of film thickness 3 nm. Since formation of the silicon thermal oxide films 510 and formation of the silicon thermal oxide films 507 are performed in different steps, the film thicknesses of the two films can be made different.

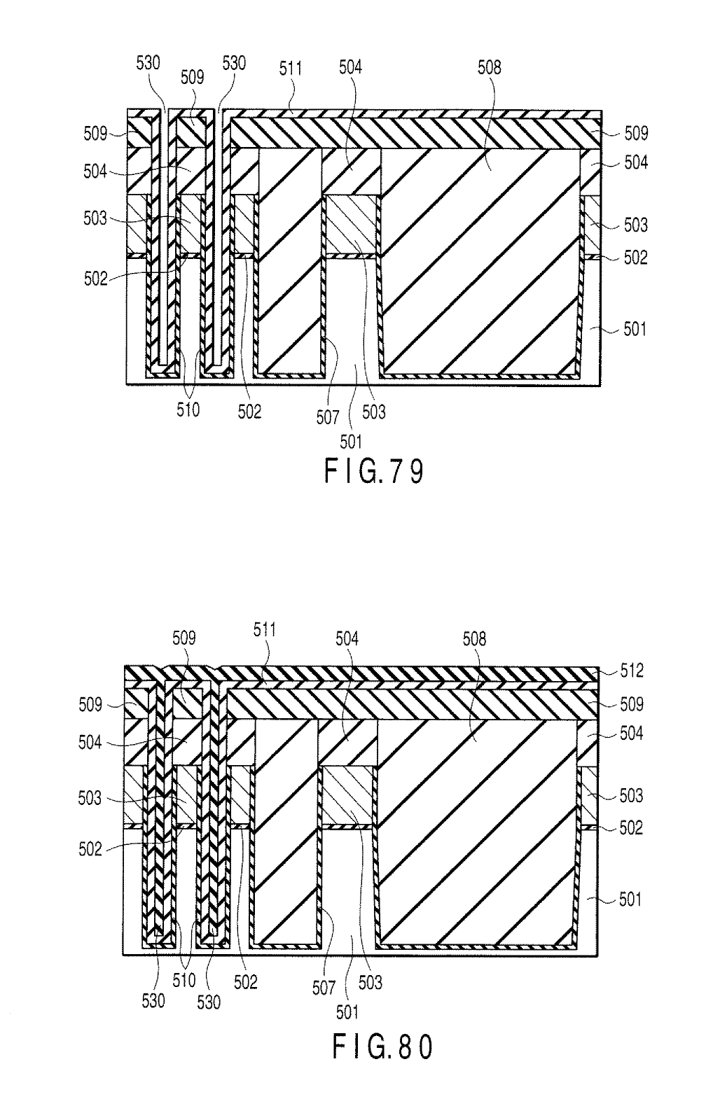

After this, as shown in FIG. 79, a silicon oxide film 511 (first insulating film) which is a liner insulating film of film thickness 15 nm is formed on the entire surface of the resultant semiconductor structure by the CVD method using silane and N₂O as raw materials. The function and purpose of the silicon oxide film 511 are the same as those of the silicon oxide film 308 explained in the third embodiment.

Next, as shown in FIG. 80, a polysilazane film 512 is formed to 50 nm on the entire surface of the resultant semiconductor structure to fully fill the isolation trenches 530. The polysilazane film 512 is an SOG film which can fill the isolation trenches 530 without causing voids.

The method for forming the polysilazane film 512 is the same as that of the first, third and fourth embodiments.

After the density of the polysilazane film 512 is enhanced by performing the annealing process in the inert gas atmosphere, the silicon oxide film 509, silicon oxide film 511 and polysilazane film 512 are polished by the CMP process with the silicon nitride film 504 used as a stopper as shown in FIG. 81. Thus, the polysilazane films 512 are left behind only in the isolation trenches 530.

Next, as shown in FIG. 82, the silicon nitride film 504 is removed by use of hot phosphoric acid. At this time, the upper portions of the polysilazane films 512 are slightly depressed due to a difference in the etching rate in the hot phosphoric acid.

After this, as shown in FIG. 83, the remaining filling insulating films (HDP-CVD silicon oxide films 508, silicon oxide films 511 and polysilazane films 512) are etched back by 60 nm by a reactive ion etching process.

Further, as shown in FIG. 84, the filling insulating films (silicon oxide films 511 and polysilazane films 512) remaining in the isolation trenches 530 of the cell portion are etched back by 80 nm by the known lithography technique and reactive ion etching technique.

Thus, the STI regions 530 in the cell portion and the STI regions 506 of the peripheral circuit portion are formed.

Next, as shown in FIG. 85, an ONO film 513 used as an electrode-electrode insulating film (IPD) is formed and a P-doped polysilicon film 514 used as control gate electrodes is formed.

Then, the P-doped polysilicon film 514, ONO film 513 and P-doped polysilicon film 503 are sequentially processed by the known lithography technique and RIE technique to form control gates and floating gates (not shown).

After this, a device with the final structure is formed by forming inter-level dielectric films (ILD) 515, 516, 517 and a multi-layered wiring structure having wirings 518, 519 and contact plugs 520, 521 as shown in FIG. 86 although a detailed explanation of the process is omitted.

As described above, the cell portion and peripheral portion can be separately formed by the manufacturing method of the semiconductor device of the present embodiment. That is, the cell portion can be filled with a film having a good filling property, for example, a polysilazane film, and the peripheral circuit portion is filled with a film having excellent processing resistance, for example, an HDP-CVD silicon oxide film. Thus, the filling insulating films can be separately and adequately used.

Since the STI region of wide width mainly used as the peripheral circuit portion can be filled only with the HDP-CVD silicon oxide film, the STI region will not be influenced by strong stress caused when the STI region is filled with a flowable insulating film. Therefore, it is possible to attain an advantage that problems of film cracking or transistor threshold voltage shift caused by the STI impurities can be solved.

Further, in the present embodiment, the polysilazane film is used as the insulating film which has fluidity at the film formation time and with which the trenches of the STI regions of narrow width are to be filled, but the trenches for STI of small width can be filled with a different type of SOG film, for example, a hydrogen silsesquioxane (HSQ) film ((HSiO_{3/2})ₙ, where n is an integer) or condensed CVD film.

As explained in the first to fifth embodiments, the structure in which the STI regions of narrow and wide width are filled with insulating films of different components can be relatively easily attained, while bad influences (for example, oxidation or shrinkage due to the heat treatment) caused by narrow and wide STI individually are suppressed.

Thus, since STI regions with extremely small dimensions can be formed together with STI regions of wide width, the semiconductor device can be further miniaturized and the performance and integration density thereof can be enhanced.

As described above, according to one aspect of this invention, it is possible to provide the manufacturing method of the semiconductor device in which STI regions of small width are formed of insulating films having a good filling property and a problem of separation of films due to stress in the insulating films of the STI regions of large width can be avoided.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A manufacturing method of a semiconductor device comprising:
forming a first isolation trench and a second isolation trench having width wider than the first isolation trench in a main surface area of a semiconductor substrate,
forming a first insulating film on the main surface area of the semiconductor substrate and in the first and second isolation trenches and narrowing width of an opening portion of the first isolation trench,
forming a second insulating film on the first insulating film by use of a high-density plasma-CVD method, forming a void in the first isolation trench while covering the opening portion of the first isolation trench and filling the second isolation trench with the second insulating film,
removing part of the second insulating film which covers the opening portion by anisotropic etching, and
filling the void with an insulating film having fluidity at a film formation time.

2. The manufacturing method of the semiconductor device according to claim 1, wherein a mask member used as a mask is left behind at an end time of the anisotropic etching process in the forming of the first isolation trench and the second isolation trench having the width wider than the first isolation trench.

3. The manufacturing method of the semiconductor device according to claim 1, wherein the narrowing the width of the opening portion of the first isolation trench includes conformally forming the first insulating film in the first isolation trench by a CVD method.

4. The manufacturing method of the semiconductor device according to claim 1, wherein the narrowing the width of the opening portion of the first isolation trench includes forming thermal oxide films by thermally oxidizing inner surfaces of the first and second isolation trenches and forming a first insulating film which is a liner insulating film on the thermal oxide films.

5. The manufacturing method of the semiconductor device according to claim 1, wherein the forming of the void in the first isolation trench while covering the opening portion of the first isolation trench and filling the second isolation trench with the second insulating film consists of performing an anisotropic film formation process by forming a film in a state where deposition and sputtering processes both occur by means of a high-density plasma-CVD method.

6. The manufacturing method of the semiconductor device according to claim 1, wherein the insulating film having fluidity at the film formation time is a spin-on glass (SOG) film formed by use of a coating material.

7. The manufacturing method of the semiconductor device according to claim 6, wherein the coating material contains one selected from a group consisting of polysilazane, hydrogen silsesquioxane ((HSiO_{3/2})ₙ, where n is an integral number) film and chemical vapor condensation film as a main component.

8. The manufacturing method of the semiconductor device according to claim 1, wherein the width of the first isolation trench after narrowing the width of the opening portion of the first isolation trench is not wider than 20 nm.

9. The manufacturing method of the semiconductor device according to claim 1, wherein the width of the second isolation trench is not less than 100 nm.

10. A manufacturing method of a semiconductor device comprising:
forming a first isolation trench in a main surface area of a semiconductor substrate,
forming a first insulating film on the main surface area of the semiconductor substrate and in the first isolation trench,
filling the first isolation trench with an insulating film having fluidity at a film formation time via the first insulating film by forming an insulating film having fluidity at the film formation time on the first insulating film,
forming a second isolation trench having width wider than the first isolation trench, and
filling the second isolation trench with a second insulating film by means of a high-density plasma-CVD method.

11. The manufacturing method of the semiconductor device according to claim 10, which further comprises forming a barrier film on the first isolation trench after the filling of the first isolation trench with the insulating film having fluidity at the film formation time and in which the forming of the second isolation trench is performed after the forming of the barrier film.

12. The manufacturing method of the semiconductor device according to claim 11, wherein the barrier film is one of a silicon oxide film and silicon nitride film.

13. The manufacturing method of the semiconductor device according to claim 10, which further comprises forming a thermal oxide film by thermally oxidizing the inner surface of the first isolation trench after the forming of the first isolation trench and before the forming of the first insulating film and in which the forming of the first insulating film consists of forming a liner insulating film on the thermal oxide film.

14. The manufacturing method of the semiconductor device according to claim 11, further comprising forming a thermal oxide film by thermally oxidizing the inner surface of the second isolation trench after the forming of the second isolation trench and before the filling of the second isolation trench with the second insulating film.

15. The manufacturing method of the semiconductor device according to claim 1, wherein the insulating film having fluidity at the film formation time is a spin-on glass (SOG) film formed by use of a coating material.

16. The manufacturing method of the semiconductor device according to claim 15, wherein the coating material contains one selected from a group consisting of polysilazane, hydrogen silsesquioxane ((HSiO_{3/2})ₙ, where n is an integral number) film and chemical vapor condensation as a main component.

17. The manufacturing method of the semiconductor device according to claim 10, wherein the width of the first isolation trench after the first insulating film is formed is not wider than 20 nm.

18. The manufacturing method of the semiconductor device according to claim 10, wherein the width of the second isolation trench is not less than 100 nm.
